(19) United States
(12) Patent Application Publication
(10) Pub. No.: US 2026/0305040 A1
(43) Pub. Date: Oct. 1, 2026

(54) DISPLAY DEVICE

(71) Applicant: LG Display Co., Ltd., Seoul (KR)

(72) Inventors: Youngmin KWON, Paju-si (KR); Hyuk Kyu KWON, Paju-si (KR)

(21) Appl. No.: 19/480,451

(22) PCT Filed: Jan. 17, 2025
(86) PCT No.: PCT/KR2025/099087

§ 371 Date: Oct. 31, 2025

(30) Foreign Application Priority Data
Feb. 22, 2024 (KR) 10-2024-0025897

(51) Int. Cl. H10H 29/855

(52) U.S. Cl. CPC H10H 29/855

(57) ABSTRACT

A display device includes a first light source unit including a plurality of first light sources, a light controller which is disposed on the first light source unit and includes a plurality of partitions overlapping at least a partial area of the active area, a second light source unit which is disposed on the light controller and includes a plurality of second light sources, a light guide plate disposed to be parallel to the second light source unit and configured to guide light provided from the second light source unit, and a display panel disposed on the light guide plate and configured to display an image using light provided from the first light source unit or the second light source unit, and the light guide plate may include a plurality of first protruding patterns which protrudes from a bottom surface and is disposed with a different density in each area.

### CROSS REFERENCE TO RELATED APPLICATION

This application is a National Stage Entry of International Patent Application No. PCT/KR 2025/099087, filed on Jan. 17, 2025, which claims priority from and the benefit of Korean Patent Application No. 10-2024-0025897, filed on Feb. 22, 2024, which is hereby incorporated by reference for all purposes as if fully set forth herein.

### BACKGROUND

### Field

Embodiments of the invention relate generally to a display device, and more particularly, to a display device in which a viewing angle is controllable.

### Discussion of the Background

As the technology in modern society develops, display devices are used in various ways to provide information to users. The display devices include not only electronic signs which simply transmit visual information in one direction, but also various electronic devices which require higher level of technology to check user's input and provide information in response to the checked input.

For example, a display device is included in a vehicle to provide various information to a driver and a passenger of the vehicle. However, the display device for the vehicle needs to appropriately display contents without interrupting the operation of the vehicle. For example, the display device needs to limit the display of the contents which may reduce the concentration on the driving while the vehicle is in operation.

The above information disclosed in this Background section is only for understanding of the background of the inventive concepts, and, therefore, it may contain information that does not constitute prior art.

### SUMMARY

An object to be achieved by the present disclosure is to provide a display device which provides contents in a first area of an active area at a wide viewing angle and provides contents in a second area at a wide viewing angle or a narrow viewing angle, based on a driving mode.

Another object to be achieved by the present disclosure is to provide a display device which improves a viewing angle required for a second area according to a driving mode by increasing a viewing angle of an image displayed in a second area in which a content is displayed at a wide viewing angle in a first mode and reducing a viewing angle of an image displayed in a second area in which a content is displayed at a narrow viewing angle in a second mode.

Still another object to be achieved by the present disclosure is to provide a display device which improves a viewing angle required for a first area by increasing a viewing angle in the first area in which a content is displayed at a wide viewing angle regardless of a driving mode.

Additional features of the inventive concepts will be set forth in the description which follows, and in part will be apparent from the description, or may be learned by practice of the inventive concepts.

According to an embodiment of the present disclosure, a display device includes a first light source unit including a plurality of first light sources, a light controller which is disposed on the first light source unit and includes a plurality of partitions overlapping at least a partial area of the active area, a second light source unit which is disposed on the light controller and includes a plurality of second light sources, a light guide plate disposed to be parallel to the second light source unit and configured to guide light provided from the second light source unit, and a display panel disposed on the light guide plate and configured to display an image using light provided from the first light source unit or the second light source unit, and the light guide plate may include a plurality of first protruding patterns which protrudes from a bottom surface and is disposed with a different density in each area.

The active area may include: a first area in which an image is displayed at a first viewing angle in a first mode and a second mode; and a second area which is adjacent to the first area in a first direction, and in the second area, an image is displayed at the first viewing angle in the first mode and an image is displayed at a second viewing angle which is smaller than the first viewing angle in the second mode.

The plurality of first protruding patterns may be disposed with a first density in the first area and is disposed with a second density which is higher than the first density in the second area.

A placement density of the plurality of first protruding patterns may be reduced as being farther from a boundary between the first area and the second area.

the placement density of the plurality of first protruding patterns may be reduced in a third area of the first area which is adjacent to the second area as being farther from the boundary between the first area and the second area, and the plurality of first protruding patterns may be disposed with a constant density in a fourth area of the first area which is adjacent to the third area in an opposite direction of the first direction.

A placement density of a first protruding pattern disposed on the second area, among the plurality of first protruding patterns, may be reduced toward the first direction, and the second light source unit may be disposed in a side of the light guide plate in the first direction.

The light guide plate further may include a plurality of second protruding patterns which protrudes from a bottom surface and has a shape different from that of the plurality of first protruding patterns.

The plurality of second protruding patterns may be disposed in the first area, but may be not disposed in the second area.

In the first area, the plurality of second protruding patterns may be disposed with a constant density.

A placement density of the plurality of second protruding patterns disposed in the first area may be smaller to a minimum value of a placement density of the plurality of first protruding patterns disposed in the first area.

The plurality of second protruding patterns may be disposed with a third density in a third area of the first area which is adjacent to the second area, and may be disposed with a fourth density which is higher than the third density in a fourth area of the first area which is adjacent to the third area in an opposite direction of the first direction.

The plurality of second protruding patterns may be disposed with a constant density in each of the third area and the fourth area.

In the third area, a placement density of the plurality of second protruding patterns may be increased as being farther from a boundary between the first area and the second area, and in the fourth area, the plurality of second protruding patterns may be disposed with a constant density.

Each of the plurality of first protruding patterns may have an asymmetric quadrangular pyramid shape.

In the first mode, the plurality of first light sources and the plurality of second light sources may emit light, and in the second mode, the plurality of first light sources may emit light, but the plurality of second light sources may not emit light.

Each of the plurality of partitions may have a rectangular shape on a side surface.

Each of the plurality of partitions may have a trapezoidal shape on a side surface.

According to another embodiment of the present disclosure, a display device includes: a first light source unit including a plurality of first light sources; a light controller which is disposed on the first light source unit and includes a plurality of partitions overlapping at least a partial area of an active area; a second light source unit which is disposed on the light controller and includes a plurality of second light sources; a light guide plate disposed to be parallel to the second light source unit and configured to guide light provided from the second light source unit; and a display panel disposed on the light guide plate and configured to display an image using light provided from the first light source unit or the second light source unit.

The light guide plate may include a plurality of first protruding patterns and a plurality of second protruding patterns which protrude from a bottom surface.

The active area may include: a first area in which an image is displayed at a first viewing angle in a first mode and a second mode; and a second area which is adjacent to the first area in a first direction, and in the second area, an image is displayed at the first viewing angle in the first mode and an image is displayed at a second viewing angle which is smaller than the first viewing angle in the second mode. The plurality of first protruding patterns may be disposed in the first area and the second area, and the plurality of second protruding patterns may be disposed in the first area. The plurality of first protruding patterns and the plurality of second protruding patterns may have different shapes.

It is to be understood that both the foregoing general description and the following detailed description are example and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this disclosure, illustrate embodiments of the invention, and together with the description serve to explain the inventive concepts.

FIG. 1 is a schematic example view of a display device according to an embodiment of the present disclosure.

FIG. 2 is an exploded schematic perspective view of a display device according to an embodiment of the present disclosure.

FIG. 3 is a schematic view illustrating an example of a display panel included in a display device according to an embodiment of the present disclosure.

FIG. 4A is a schematic side view illustrating an example of a light controller included in a display device of FIG. 2.

FIG. 4B is an enlarged schematic view illustrating an example of a part EA1 of FIG. 4A.

FIG. 5A is a schematic side view illustrating another example of a light controller included in a display device of FIG. 2.

FIG. 5B is an enlarged schematic view illustrating an example of a part EA2 of FIG. 5A.

FIG. 6 is a schematic side view illustrating still another example of a light controller included in a display device of FIG. 2.

FIG. 7 is a schematic side view illustrating still another example of a light controller included in a display device of FIG. 2.

FIG. 8A is a schematic side view illustrating still another example of a light controller included in a display device of FIG. 2.

FIG. 8B is an enlarged schematic view illustrating an example of a part EA3 of FIG. 8A.

FIG. 9 is a schematic side view illustrating still another example of a light controller included in a display device of FIG. 2.

FIG. 10 is a schematic side view of a display device according to an embodiment of the present disclosure.

FIG. 11 is a schematic view illustrating an example of a first protruding pattern included in a light guide plate of a display device of FIG. 10.

FIG. 12 is a schematic rear view illustrating an example of a light guide plate included in a display device of FIG. 10.

FIG. 13 is a schematic graph for explaining an example of a placement density of a first protruding pattern included in a light guide plate of FIG. 12.

FIG. 14 is an exploded schematic perspective view of a display device according to another embodiment of the present disclosure.

FIG. 15 is a schematic side view of a display device according to another embodiment of the present disclosure.

FIG. 16 is a schematic rear view illustrating an example of a light guide plate included in a display device of FIG. 15.

FIG. 17 is a schematic graph for explaining an example of a placement density of a first protruding pattern and a second protruding pattern included in a light guide plate of FIG. 16.

FIG. 18 is a schematic rear view illustrating another example of a light guide plate included in a display device of FIG. 15.

FIGS. 19A and 19B are schematic graphs for explaining an example of a placement density of a first protruding pattern and a second protruding pattern included in a light guide plate of FIG. 18.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this disclosure, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software.

It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When an element or layer is disposed “on” another element or layer, another layer or another element may be interposed directly on the other element or therebetween.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

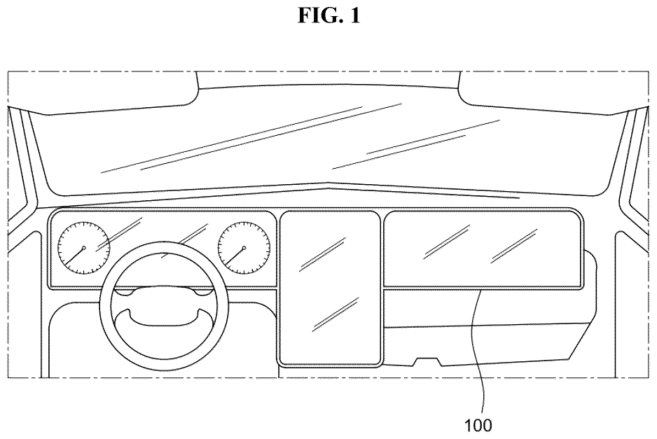

FIG. 1 is an example view of a display device according to an embodiment of the present disclosure.

Referring to FIG. 1, the display device 100 may be disposed in at least a part of a dashboard of a vehicle. The dashboard of the vehicle may include a configuration disposed in a front surface of front seats (for example, a driver seat and a front passenger seat) of the vehicle. For example, on the dashboard of the vehicle, an input configuration for manipulating various functions (for example, an air-conditioner, an audio system, or a navigation system) in the vehicle may be disposed.

The display device 100 may be disposed on the dashboard of the vehicle to operate as an input unit which manipulates at least a part of various functions of the vehicle.

The display device 100 may provide various information related to the vehicle, for example, operation information of the vehicle (for example, a current speed of the vehicle, a remaining fuel amount, or a mileage) or information about parts of the vehicle (for example, a damage level of a vehicle tire).

The display device 100 may be disposed across the driver seat and the front passenger seat disposed in the front seats of the vehicle. A user of the display device 100 may include a driver of the vehicle and a passenger riding on the front passenger seat. Both the vehicle driver and the passenger may use the display device 100.

A part of the display device 100 may only be illustrated in FIG. 1. The display device 100 illustrated in FIG. 1 may represent a display panel, among various configurations included in the display device 100. Particularly, for example, the display device 100 illustrated in FIG. 1 may represent at least a part of an active area and a non-active area of the display panel. Among the configurations of the display device 100, configurations other than the parts illustrated in FIG. 1 may be mounted inside the vehicle (or at least a part of the inside of the vehicle).

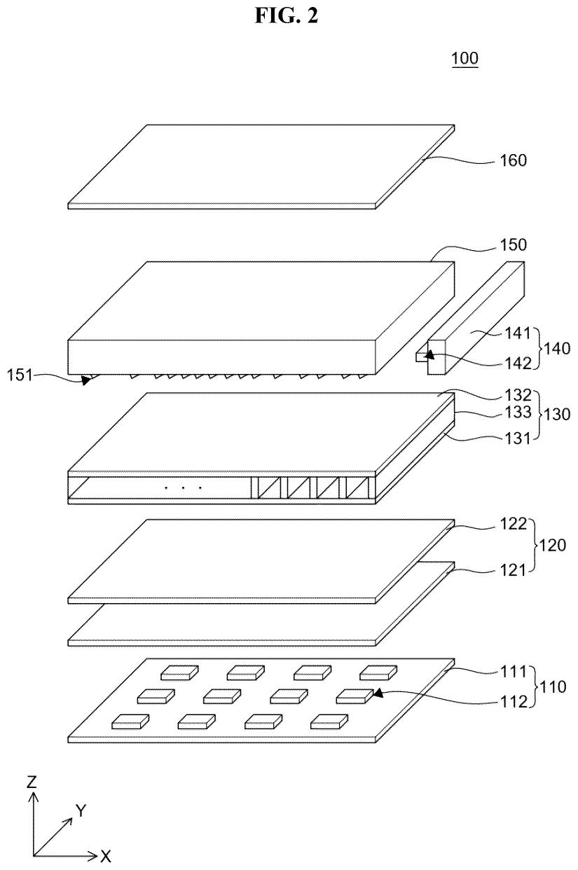

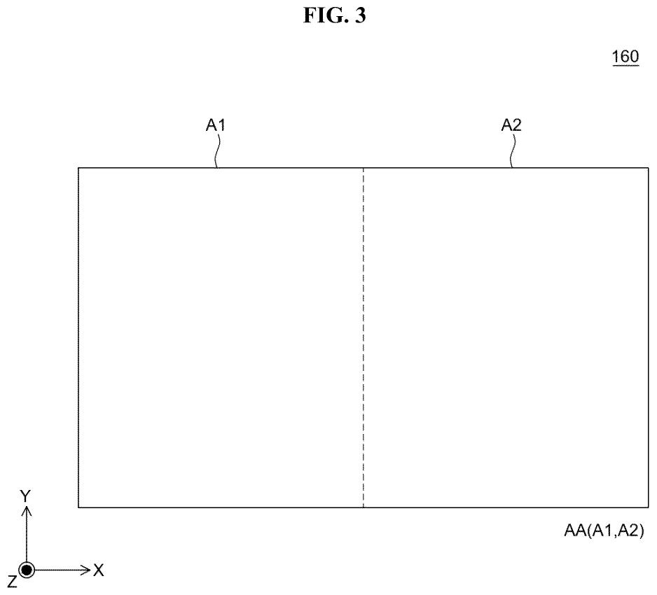

FIG. 2 is an exploded schematic perspective view of a display device according to an embodiment of the present disclosure. FIG. 3 is a schematic view illustrating an example of a display panel of a display device according to an embodiment of the present disclosure.

For the convenience of description, hereinafter, a horizontal direction on the plain is illustrated as a first direction X and a vertical direction on the plane is illustrated as a second direction Y. Further, a normal direction of a plane defined by the first direction X and the second direction Y, for example, a thickness direction of the display device 100 may be defined as a third direction Z.

Referring to FIG. 2, the display device 100 according to the embodiment of the present disclosure may include a first light source unit 110, at least an optical sheet 120, a light controller 130, a second light source unit 140, a light guide plate 150, and a display panel 160.

The display panel 160 may generate an image to be provided to a user using light provided from a light source unit disposed therebelow. For example, the display panel 160 may adjust a transmittance for light provided from the first light source unit 110 and/or the second light source unit 140 disposed therebelow to display an image.

As the display panel 160, a liquid crystal display panel may be applied. For example, the display panel 160 may include a bottom substrate, a top substrate which is opposite to the bottom substrate, and a liquid crystal layer disposed between the bottom substrate and the top substrate. Here, the liquid crystal layer may be driven by a vertical field driving method, such as a twisted nematic (TN) mode and a vertical alignment (VA) mode, or a horizontal field driving method, such as an in-plane switching (IPS) mode and a fringe field switching (FFS) mode, but is not limited thereto.

The display panel 160 may include an active area in which an image is displayed and a non-active area which encloses the active area.

The active area of the display panel 160 may be partitioned into a plurality of areas. In other words, the active area may include a plurality of areas.

For example, further referring to FIG. 3, the active area AA of the display panel 160 may include a plurality of areas disposed along the first direction X. For example, the active area AA may include a first area A1 and a second area A2 which is adjacent to the first area A1 in the first direction X.

According to the embodiment, the first area A1 and the second area A2 of the display panel 160 may be disposed across a driver seat and a front passenger seat disposed in front seats of the vehicle which have been described with reference to FIG. 1 to provide various information to a driver and a passenger of the vehicle. For example, the first area A1 may be correspond to the driver seat, and the second area A2 may be correspond to the front passenger seat in the vehicle. Each of the first area A1 and the second area A2 of the display panel 160 may display different information images to the user. For example, the first area A1 of the display panel 160 may include an area provided to the driver seat disposed on the front seat of the vehicle and/or an area provided between the driver seat and the front passenger seat, for example, a CID area to provide information such as a driving speed, RPM, an engine temperature, and a fuel amount. The second area A2 of the display panel 160 may be an area provided to the front passenger seat disposed on the front seat of the vehicle, for example, a CDD area to provide entertainment functions and seat information for the passenger sitting in the front passenger seat. However, such area division is for the convenience of description and the first area A1 and the second area A2 in the display panel 160 may be defined in various ways based on the design.

When the display panel 160 is used for the vehicle which has been described with reference to FIG. 1, a field of view of at least partial area of the display panel 160 may need to be restricted according to the user's request. For example, images displayed in the second area A2 which provides the entertainment function and the seat information for the passenger sitting on the front passenger seat may interrupt the driving of the driver. Accordingly, according to the user's request, the field of view of the image displayed in the second area A2 needs to be restricted.

For example, according to the driving mode of the display device 100, in the first mode, both the first area A1 and the second area A2 of the display panel 160 may be controlled in a wide field-of-view mode (share mode) to display an image. In the second mode, at least a part of the display panel 160, for example, the second area A2 may be controlled in a narrow field-of-view mode (private mode) to display an image. To this end, the display device 100 may control whether to allow the second light source unit 140 disposed on the top, among the plurality of light source units disposed below the display panel 160, to emit light to control the display panel 160 in the first mode or the second mode.

Referring to FIG. 2, a first light source unit 110, at least an optical sheet 120, a light controller 130, a second light source unit 140, and a light guide plate 150 may be disposed below the display panel 160.

The first light source unit 110 may generate light and may provide the generated light to the third direction Z (or thickness direction), for example, toward the optical sheet 120. The first light source unit 110 may be disposed below the optical sheet 120. For example, the first light source unit 110 may be a direct type backlight assembly.

The first light source unit 110 may include a first circuit board 111 and a plurality of first light sources 112 disposed on the first circuit board 111 and protruded upward from the first circuit board 111.

The first circuit board 111 may include a driving circuit which drives the plurality of first light sources 112. The driving circuit of the first circuit board 111 may generate an electrical signal to drive the plurality of first light sources 112 and may supply the electrical signal to the plurality of first light sources 112. However, the present disclosure is not limited thereto and the driving circuit may be disposed at the outside of the first circuit board 111.

The plurality of first light sources 112 may be mounted on the first circuit board 111. For example, the plurality of first light sources 112 may be disposed on the first circuit board 111 to be spaced apart from each other along the first direction X and the second direction Y to be mounted on a top surface which is one surface of the first circuit board 111. For example, the plurality of first light sources 112 may be disposed on the first circuit board 111 in a matrix, but is not limited thereto.

Each of the plurality of first light sources 112 may be formed to emit white light, but is not limited thereto and the plurality of first light sources 112 may be formed to emit light with any one wavelength of red, green, and blue.

As the plurality of first light sources 112, a light emission diode (LED), a cold cathode fluorescent lamp (CCFL), or an external electrode fluorescent lamp may be used, but it is not limited thereto.

At least an optical sheet 120 may be disposed on the first light source unit 110.

On the first light source unit 110, a plurality of optical sheets which diffuses or condenses light incident from the first light source unit 110 may be included.

For example, the optical sheet 120 may include a first optical sheet 121 and a second optical sheet 122 which is disposed on the first optical sheet 121. The first optical sheet 121 may diffuse light provided from the first light source unit 110 and allow light to travel upward, for example, in the third direction Z. For example, the first optical sheet 121 may be a diffusion sheet. The second optical sheet 122 may condense light which has passed through the first optical sheet 121 configured to allow light to travel upward, for example, in the third direction Z. For example, the second optical sheet 122 may be a prism sheet.

However, the present disclosure is not limited thereto, and the optical sheet 120 may include another optical sheet, in addition to the first optical sheet 121 and the second optical sheet 122. For example, the optical sheet 120 further may include a luminance improvement sheet, such as a protective sheet or a dual brightness enhancement film (DBEF), or may include a composite optical sheet in which the diffusion sheet and the prism sheet are integrated, instead of the first optical sheet 121 and the second optical sheet 122.

The light controller 130 may be disposed on the optical sheet 120.

The light controller 130 may control a viewing angle of light provided from the bottom. For example, the light controller 130 may restrict a viewing angle or an emission angle in the first direction X, of light which is emitted from the first light source unit 110 to pass through the optical sheet 120 and travel in a third direction Z which is perpendicular to the active area AA. In particular, the light controller 130 may reduce or narrow a profile of light which is emitted from the first light source unit 110 to be incident into the light controller 130, in the first direction X. For example, a viewing angle of the first direction X of an image which is displayed by the light may be reduced.

To this end, the light controller 130 may include a first support member 131, a second support member 132 which is disposed opposite to the first support member 131, and a plurality of partitions 133 which is interposed between the first support member 131 and the second support member 132. The term, partition used, in the present disclosure, is used for the convenience of description and may be defined as a term “louver” or a term “viewing angle control pattern”, instead of the partition.

Each of the plurality of partitions 133 may extend between the first support member 131 and the second support member 132 in the second direction Y and may be disposed to be spaced apart from each other along the first direction X. For example, a profile of light which is incident to the light controller 130, for example, an area spaced between the plurality of partitions 133, may be narrowed in the first direction X, by the plurality of partitions 133 disposed to be spaced apart from each other. Most of light which are restricted in the front direction, for example, in the third direction Z, may be provided to the display panel 160.

Accordingly, in an area in which the plurality of partitions 133 of the light controller 130 is disposed, the light may be provided in a first range and in an area in which the plurality of partitions 133 of the first light controller 130 is not disposed, the light may be provided in a second range which is larger than the first range. Accordingly, in the case of the image which is displayed with light emitted from the first light source unit 110, in an area of the active area AA overlapping an area in which the plurality of partitions 133 of the light controller 130 is disposed, the image may be displayed at the second viewing angle. In an area overlapping the area in which the plurality of partitions 133 is not disposed, the image may be displayed at the first viewing angle. The first viewing angle may be larger than the second viewing angle. For example, the first viewing angle may be defined as a wide viewing angle, and the second viewing angle may be defined as a narrow viewing angle.

Further, the light controller 130 may control the viewing angle of the image which is displayed by light emitted from the first light source unit 110 to be different in each area. For example, the light controller 130 may control a viewing angle of light which is provided from the bottom to travel in the third direction Z for each area of the active area AA. For example, the light controller 130 may control a viewing angle of the image which is displayed by light emitted from the first light source unit 110 in the second area A2 of the active area AA.

For example, the plurality of partitions 133 may be disposed in an area overlapping the second area A2. Accordingly, in the case of the image displayed by light emitted from the first light source unit 110, in the second area A2 overlapping an area in which the plurality of partitions 133 is disposed, the viewing angle may be controlled to the second viewing angle to display an image. In the other area, for example, in the first area A1, the viewing angle may be not controlled and the image may be displayed at the first viewing angle.

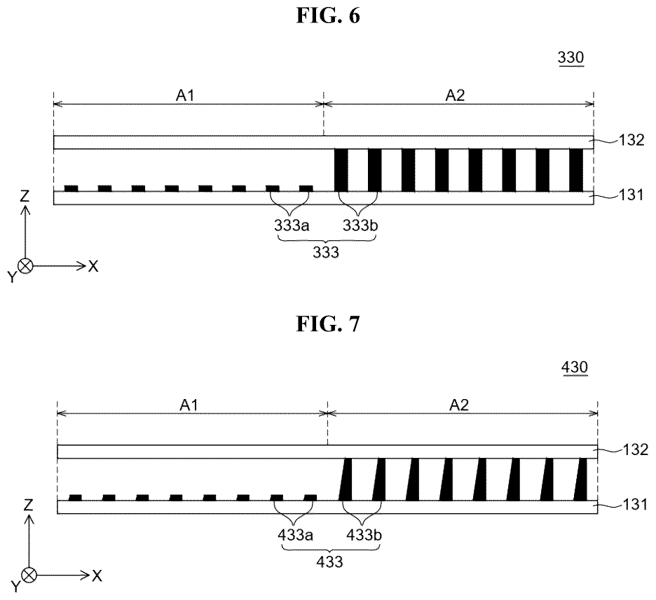

However, it is merely illustrative and the area in which the partition 133 is disposed is not limited thereto. For example, the plurality of partitions 133 may be disposed on the entire area overlapping the active area AA. It will be described in detail below with reference to FIGS. 6, 7, 8, and 9.

The second light source unit 140 and the light guide plate 150 may be disposed on the light controller 130.

The second light source unit 140 may generate light and may provide the generated light to the light guide plate 150. The second light source unit 140 may be disposed on a side surface of the light guide plate 150. For example, the second light source unit 140 may be an edge type backlight assembly.

The second light source unit 140 may include a second circuit board 141 and a plurality of second light sources 142 disposed on the second circuit board 141. For example, the plurality of second light sources 142 may be protruded from the second circuit board 141 in the second direction Y.

The second circuit board 141 may include a driving circuit which drives the plurality of second light sources 142. The driving circuit of the second circuit board 141 may generate an electrical signal to drive the plurality of second light sources 142 and supply the electrical signal to the plurality of second light sources 142. However, the present disclosure is not limited thereto and the driving circuit may be disposed at the outside of the second circuit board 141.

The second circuit board 141 may be disposed on a side surface of the light guide plate 150. In particular, the second circuit board 141 may be disposed to be parallel to the light guide plate 150. For example, the second circuit board 141 may have a shape which corresponds to one short side of the light guide plate 150 to extend along a length direction of the short side, for example, along the second direction Y. However, the present disclosure is not limited thereto and the second circuit board 141 may be disposed so as to correspond to one long side of the light guide plate 150.

Further, the plurality of second light sources 142 may be mounted on the second circuit board 141. For example, the plurality of second light sources 142 may be disposed on the second circuit board 141 to be spaced apart from each other along the second direction Y to be mounted on a top surface which is an surface of the second circuit board 141.

Each of the plurality of second light sources 142 may be formed to emit white light, but is not limited thereto and the plurality of second light sources 142 may be formed to emit light with any one wavelength of red, green, and blue.

As the plurality of second light sources 142, a light emission diode (LED), a cold cathode fluorescent lamp (CCFL), or an external electrode fluorescent lamp may be used, but it is not limited thereto.

The light guide plate 150 may be disposed on the light controller 130 and may be disposed on a side portion of the second light source unit 140. For example, the light guide plate 150 may be disposed on the substantially same planar surface as the second light source unit 140.

The light guide plate 150 may be formed of a material including glass, quartz, or polymer having transparency, to efficiently guide the light. For example, the polymer may be formed of a material having a predetermined refractive index, such as acrylic resin including polymethylmethacrylate (PMMA) or polycarbonate (PC).

The light guide plate 150 may guide light provided from the second light source unit 140 to allow the light to travel in a direction toward the display panel 160, for example, in the third direction Z. For example, light which is incident from the second light source unit 140, through a side surface on which the second light source unit 140 is disposed, may change the traveling direction to the third direction Z which is directed to the display panel 160, by total reflection, while traveling in the light guide plate 150. Therefore, a uniform surface light source may be provided toward the display panel 160.

Further, the light which is provided via the optical sheet 120 and the light controller 130 from the first light source unit 110 may travel to the third direction Z which is directed to the display panel 160 by means of the light guide plate 150.

The light guide plate 150 may include a plurality of first protruding patterns 151 disposed on a lower surface. For example, each of the plurality of first protruding patterns 151 may be formed as a relief which protrudes downward from the lower surface of the light guide plate 150, for example, in an opposite direction of the third direction Z.

Each of the plurality of first protruding patterns 151 may include a material having a refractive index which is different from that of air, for example, a refractive index which is higher than the refractive index of air. For example, each of the plurality of first protruding patterns 151 may include the same material as the light guide plate 150 so that each of the plurality of first protruding patterns 151 may have the same refractive index as the light guide plate 150, but is not limited thereto.

The plurality of first protruding patterns 151 may be formed to protrude in a lower direction of the light guide plate 150, for example, in an opposite direction of the third direction Z. The plurality of first protruding patterns 151 may be disposed on the bottom surface of the light guide plate 150 with a different density in each area. For example, the farther from the boundary of the first area A1 and the second area A2, for example, the farther from the boundary in the first direction X and/or the opposite direction of the first direction X, the lower the placement density of the first protruding patterns 151.

Each of the plurality of first protruding patterns 151 may have planes, for example, four inclined surfaces which form a predetermined angle with a surface defined by the first direction X and the second direction Y. For example, the plurality of first protruding patterns 151 may have a square pyramid shape. The path of light which is incident to the light guide plate 150 may be controlled by the plurality of first protruding patterns 151 as described above.

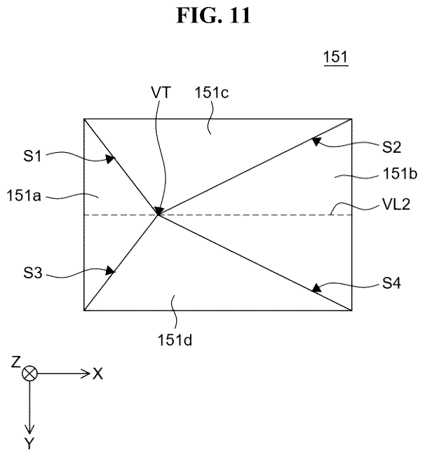

The placement density and the shape of the plurality of first protruding patterns 151 may be described in detail below with reference to FIGS. 10, 11, and 12.

As described above, the driving mode of the display device 100 may be controlled based on whether the second light source 142 included in the second light source unit 140 emits light.

For example, in the first mode, all the plurality of first light sources 112 of the first light source unit 110 and the plurality of second light sources 142 of the second light source unit 140 may emit light. For example, even though in at least a partial area of the active area AA, for example, in an area overlapping the second area A2, a viewing angle of light emitted from the first light source unit 110 may be controlled by the light controller 130, light emitted from the second light source unit 140 may travel in the third direction Z which is a direction toward the display panel 160 by the light guide plate 150 to be provided in the entire active area AA. Therefore, the image may be displayed at the first viewing angle in the entire area of the display panel 160. Accordingly, in the first mode, the image may be displayed in a wide field-of-view mode (share mode) in the entire active area AA, for example, in both the first area Al and the second area A2.

Further, in the second mode, the plurality of first light sources 112 of the first light source unit 110 may emit light, and the plurality of second light sources 142 of the second light source unit 140 may not emit light. Therefore, an image which is displayed by the display panel 160 in the second mode may be implemented only by light provided from the first light source unit 110. For example, in an area of the active area AA which overlaps the second area A2, the viewing angle of the light emitted from the first light source unit 110 may be controlled by the light controller 130. Therefore, in the first area A1 of the display panel 160, the image may be displayed at the first viewing angle and in the second area A2 of the display panel 160, the image may be displayed at the second viewing angle. Accordingly, in the second mode, the image may be displayed in the wide field-of-view mode (share mode) in the first area A1 of the active area AA and the image may be displayed in the narrow field-of-view mode (private mode) in the second area A2 of the active area AA.

As described above, the display device 100 according to the embodiment of the present disclosure may control the second light source unit 140 disposed on the top, among the plurality of light sources disposed below the display panel 160, in particular, the first light source unit 110 and the second light source unit 140 to emit light. By doing this, the display device may control the display panel 160 in the first mode or the second mode.

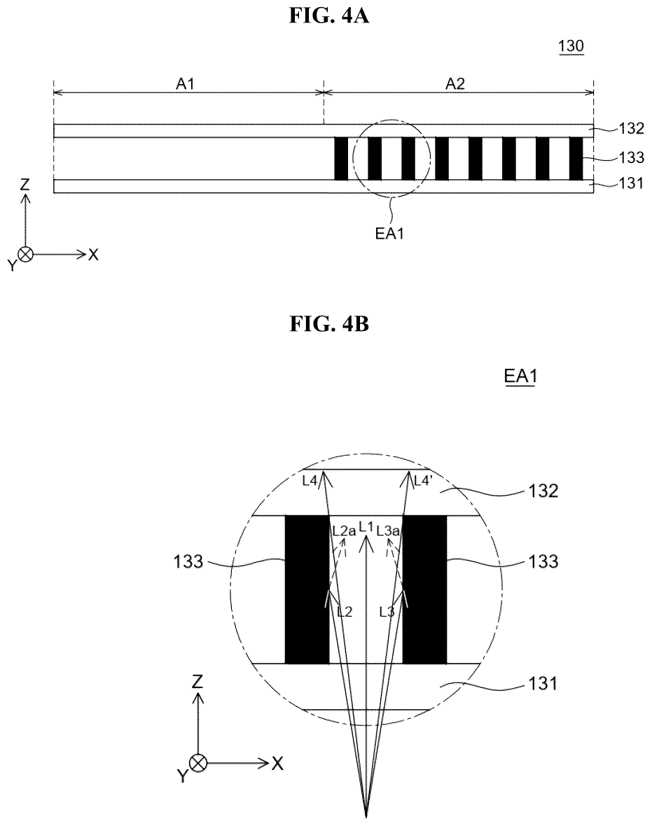

Hereinafter, the light controller 130 of the display device 100 according to the embodiment of the present disclosure will be described in more detail with reference to FIGS. 4A, 4B, 5A, 5B, 6, 7, 8A, 8B, and 9. The first protruding pattern 151 included in the light guide plate 150 of the display device 100 according to the embodiment of the present disclosure will be described in more detail with reference to FIGS. 10, 11, and 12.

FIG. 4A is a schematic side view illustrating an example of a light controller included in a display device of FIG. 2. FIG. 4B is an enlarged schematic view illustrating an example of a part EA1 of FIG. 4A.

The light controller 130 illustrated in FIG. 4A may represent an embodiment of the light controller 130 included in the display device 100 which has been described with reference to FIG. 2.

Referring to FIGS. 2 and 4A, the light controller 130 may include a first support member 131, a second support member 132 which is opposite to the first support member 131, and a plurality of partitions 133 disposed between the first support member 131 and the second support member 132. By doing this, the light controller may control a viewing angle or an emission angle of light which travels toward the third direction Z which is perpendicular to the active area AA, according to the first direction X.

The first support member 131 and the second support member 132 may be disposed to be spaced apart from each other with respect to the partition 133 therebetween. The first support member 131 may be disposed below the plurality of partitions 133 configured to support the plurality of partitions 133, and the second support member 132 may be disposed above the plurality of partitions 133 configured to support the plurality of partitions 133.

However, it is not limited thereto and bottom surfaces of the plurality of partitions 133 are in contact with the first support member 131 and top surfaces of the plurality of partitions 133 may be spaced apart from the second support member 132.

The first support member 131 and the second support member 132 may include a transparent material to allow light to pass therethrough. For example, each of the first support member 131 and the second support member 132 may include a plastic material. For example, each of the first support member 131 and the second support member 132 may include polycarbonate. However, the material of each of the first support member 131 and the second support member 132 is not limited thereto. According to the embodiment, each of the first support member 131 and the second support member 132 may include polymer, such as polystyrene, polyvinyl alcohol, polymethyl methacrylate, polyethersulfone, polyacrylate, polyetherimide, polyethylene naphthalate, polyethylene terephthalate, polyphenylene sulfide, polyarylate, or polyimide.

The plurality of partitions 133 may be disposed between the first support member 131 and the second support member 132. Each of the plurality of partitions 133 may be coupled to the first support member 131 and the second support member 132 by means of a transparent adhesive, but is not limited thereto.

Each of the plurality of partitions 133 may extend along the second direction Y and may be disposed to be spaced apart from each other along the first direction X.

Accordingly, a space may be formed between the plurality of partitions 133. Such a space may be filled with air or a transparent insulating material, but is not limited thereto.

An interval along the first direction X, between two adjacent partitions 133, among the plurality of partitions 133, may be determined by comprehensively considering a thickness of the light controller 130, an emission angle of light emitted from the light controller 130, and a distance between the light controller 130 and the display panel 160. By doing this, the image displayed by the light provided from the first light source unit 110 may be displayed on the second area A2 at the second viewing angle.

Each of the plurality of partitions 133 may include a light absorption material or may be coated with a light absorbing agent to absorb light entering from the outside. For example, each of the plurality of partitions 133 may include a carbon based black pigment.

However, a material of the plurality of partitions 133 is not limited thereto. Each of the plurality of partitions 133 may include at least one of titanium (Ti), tungsten (W), chromium (Cr), molybdenum (Mo), an alloy of molybdenum (Mo) and titanium (Ti) (MoTi), vanadium (V), niobium (Nb), silicon nitride (SiN), titanium nitride (TiN), silicon carbide (SiC), tantalum (Ta), manganese (Mn), cobalt (Co), nickel (Ni), copper oxide (CuO), aluminum oxide (Al2O3), iron oxide (Fe3O4), and tantalum oxide (Ta2O5) having a high light absorptance or may include an organic material having a high light absorptance.

Further, each of the plurality of partitions 133 may have a rectangular shape on a side surface. For example, each of the plurality of partitions 133 may have a rectangular shape as seen from a plane defined by the first direction X and the third direction Z. Therefore, a top surface and a bottom surface of each of the plurality of partitions 133 may be parallel to the first support member 131 and the second support member 132. Both side surfaces of the plurality of partitions 133 may be perpendicular to the first support member 131 and the second support member 132. For example, both side surfaces of the plurality of partitions 133 may be parallel to the third direction Z which is perpendicular to the first support member 131 and the second support member 132.

An emission angle in the first direction X of light which is emitted from the light controller 130 may be restricted by the plurality of partitions 133. According to the present disclosure, an emission angle may refer to an angle formed by a traveling direction of light emitted from the light controller 130 and the third direction Z on the side surface, for example, the plane defined by the first direction X and the third direction Z.

To be more specific, further referring to FIG. 4B, a profile of light provided from the bottom of the light controller 130, for example, light provided from the first light source unit 110 may be reduced or narrowed along the first direction X by the light controller 130 so that the emission angle of the corresponding light in the first direction X may be restricted.

For example, among light provided from the bottom of the light controller 130, first light L1 having a light path formed in the third direction Z which is a vertical direction, between two separated partitions 133, may not be blocked by the partition 133, but may be emitted to the outside, in particular, the upward direction of the light controller 130.

Further, among light provided from the bottom of the light controller 130, light which passes through the upper end inside of two separated partitions 133, in particular, light between fourth light L4 and fourth′ light L4′ may be emitted to an upward direction of the light controller 130.

However, when a light path is formed in a direction having a predetermined angle with respect to the third direction Z along the first direction X between two separated partitions 133 and the partition 133 is located on the light path, among light provided from the bottom of the light controller 130, at least some of light may be blocked by the partition 133. In particular, light provided from the bottom of the light controller 130 at an angle larger than an incident angle of the fourth light L4 and fourth′ light L4′ may be blocked by the plurality of partitions 133 so as not to be emitted to an upward direction of the light controller 130. For example, at least some of second light L2 and the third light L3 provided from the bottom of the light controller 130 may be absorbed by the partition 133 and may be not emitted to the outside.

In the case of light with a light path on which the partition 133 is located, each of the plurality of partitions 133 may include a light absorption material or is coated with the light absorption agent so that most light is absorbed by the partition 133. However, the remaining light which is not absorbed by the partition 133 is totally reflected from the partition 133 to be emitted to the outside. For example, second light L2a of the second light L2 which is not absorbed by the partition 133 and third light L3a of the third light L3 which is not absorbed by the partition 133 are totally reflected from the partition 133 to be emitted to the outside.

Referring to FIG. 4A, a height of each of the plurality of partitions 133 may be substantially the same as a length of a space between the first support member 131 and the second support member 132 along the third direction Z. However, the present disclosure is not limited thereto and the height of each of the plurality of partitions 133 along the third direction Z may be smaller than a length of the space between the first support member 131 and the second support member 132 along the third direction Z. In the present disclosure, the height may refer to a length or a distance along the third direction Z.

Further, the plurality of partitions 133 may be disposed on the second area A2 and may not be disposed on the first area A1. For example, as described above, in the second area A2 in which the plurality of partitions 133 is disposed, an emission angle of the light in the first direction X is restricted to provide the light in the first range. Further, in the first area A1 in which the plurality of partitions 133 is not disposed, an emission angle of the light is not restricted to provide the light in the second range which is larger than the first range.

Accordingly, in the case of an image which is displayed by light emitted from the first light source unit 110 disposed below the light controller 130, in the second area A2 of the active area AA overlapping an area in which the plurality of partitions 133 is disposed, the image may be displayed at the second viewing angle, for example, at a narrow viewing angle. Further, in the first area A1 overlapping an area in which the plurality of partitions 133 is not disposed, the image may be displayed at the first viewing angle, for example, at a wide viewing angle.

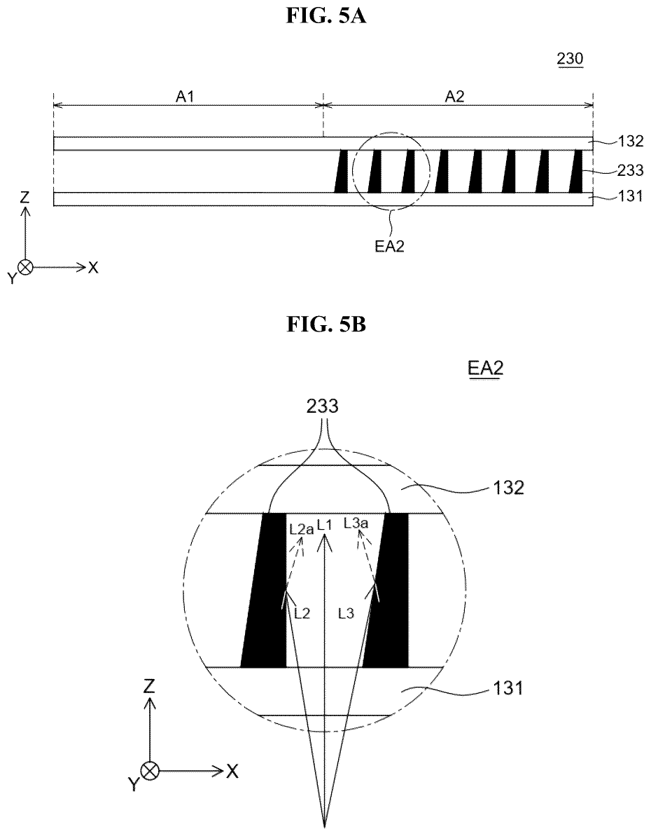

FIG. 5A is a schematic side view illustrating another example of a light controller included in a display device of FIG. 2. FIG. 5B is an enlarged schematic view illustrating an example of a part EA2 of FIG. 5a.

A light controller 230 illustrated in FIG. 5A may represent another example of the light controller 130 included in the display device 100 which has been described with reference to FIG. 2.

Further, FIGS. 5A and 5B may illustrate a modified embodiment of the embodiment of FIGS. 4A and 4B with regard to a shape of a plurality of partitions 233 included in the light controller 230. Accordingly, in FIGS. 5A and 5B, in order to avoid a redundant description, differences from the above-described embodiments will be mainly described.

Referring to FIGS. 2 and 5A, the light controller 230 may include a first support member 131, a second support member 132 which is opposite to the first support member 131, and a plurality of partitions 233 disposed between the first support member 131 and the second support member 132. By doing this, the light controller may control a viewing angle or an emission angle of light which travels toward the third direction Z which is perpendicular to the active area AA, according to the first direction X.

The plurality of partitions 233 may be disposed between the first support member 131 and the second support member 132. For example, each of the plurality of partitions 233 may extend along the second direction Y and may be disposed to be spaced apart from each other along the first direction X. Accordingly, a space may be formed between the plurality of partitions 233.

Each of the plurality of partitions 233 may have the trapezoidal shape on a side surface. For example, each of the plurality of partitions 233 may have a trapezoidal shape as seen from a plane defined by the first direction X and the third direction Z. Accordingly, a top surface and a bottom surface of each of the plurality of partitions 233 may be parallel to the first support member 131 and the second support member 132. A side surface of each of the plurality of partitions may be perpendicular to the first support member 131 and the second support member 132, and the other side surface of each of the plurality of partitions 233 may have an inclined plane at a predetermined angle with respect to the first support member 131 and the second support member 132. For example, a side surface located closer to the first direction X, between both side surfaces of each other plurality of partitions 233, may be parallel to the third direction Z which is perpendicular to the first support member 131 and the second support member 132. The other side surface located in the opposite direction to the first direction X, between both side surfaces of each other plurality of partitions 233, may have an inclined plane at a predetermined angle with respect to the third direction Z.

Accordingly, an emission angle of light emitted from the light controller 230 in the first direction X may be more effectively restricted by the plurality of partitions 233 having a trapezoidal shape on the side surface.

To be more specific, further referring to FIG. 5B, a profile of light provided from the bottom of the light controller 230, for example, light supplied from the first light source unit 110 may be reduced or narrowed along the first direction X by the light controller 230 so that the emission angle of the corresponding light in the first direction X may be restricted.

Particularly, among light provided from the bottom of the light controller 230, when a light path is formed in a direction having a predetermined angle along the first direction X with respect to the third direction Z, between two separated partitions 233, and the inclined side surface of the partition 233 may be located on the light path, if the remaining light of light which is not absorbed by the partition 233 is totally reflected, the light may be guided more toward the third direction Z which is a vertical direction, as compared with the case when the light is totally reflected by a vertical side surface of the partition 233. For example, at least a part of the second light L2 which is provided from the bottom of the light controller 230 to travel to the vertical side surface of the partition 233 is absorbed by the partition 233 and second light L2a which is not absorbed by the partition 233 is totally reflected from the vertical side surface of the partition 233. At least a part of the third light L3 which is provided from the bottom of the light controller 230 to travel to the inclined side surface of the partition 233 may be absorbed by the partition 233 and third light L3a which is not absorbed by the partition 233 may be totally reflected from the inclined side surface of the partition 233. Here, based on the difference in the incident angles on the vertical side surface and the inclined side surface of the partition 233, the third light L3a which is totally reflected by the inclined side surface of the partition 233 may be guided to the third direction Z which is a vertical direction more than the second light L2a which is totally reflected by the vertical side surface of the partition 233. Accordingly, more light which is directed to the display panel 160 in the second area A2 may be condensed.

Further, the third light L3a which is totally reflected by the inclined side surface of the partition 233 may travel toward the opposite direction to the first direction X in which the first area A1 is located. When the third light is totally reflected, the third light may be more guided to the third direction Z which is a vertical direction by the incident angle by the inclined side surface. Accordingly, as compared with the third light L3a which is totally reflected by the vertical side surface of the partition 133 which has been described with reference to FIG. 4A, the third light L3a which is totally reflected by the inclined side surface of the partition 233 which has been described with reference to FIG. 5A, may be more shifted to the first direction X.

Accordingly, in the case of the image which is displayed on the second area A2 by the light provided from the first light source unit 110, a viewing angle to the first area A1 may be more effectively restricted.

FIG. 6 is a schematic side view illustrating still another example of a light controller included in a display device of FIG. 2.

A light controller 330 illustrated in FIG. 6 may represent still another example of the light controller 130 included in the display device 100 which has been described with reference to FIG. 2.

Further, FIG. 6 may illustrate a modified embodiment of the embodiment of FIG. 4A with regard to an area in which a plurality of partitions 333 included in the light controller 330 is disposed. Accordingly, in FIG. 6, in order to avoid a redundant description, differences from the above-described embodiments will be mainly described.

Referring to FIGS. 2 and 6, the light controller 330 may include a first support member 131, a second support member 132 which is opposite to the first support member 131, and a plurality of partitions 333 disposed between the first support member 131 and the second support member 132. By doing this, the light controller may control a viewing angle or an emission angle of light which travels toward the third direction Z which is perpendicular to the active area AA, according to the first direction X.

The plurality of partitions 333 may be disposed on the entire active area AA. For example, the plurality of partitions 333 may include a plurality of first partitions 333a disposed on the first area A1 and a plurality of second partitions 333b disposed on the second area A2.

The plurality of first partitions 333a may be disposed between the first support member 131 and the second support member 132 on the first area A1. For example, each of the plurality of first partitions 333a may extend along the second direction Y and may be disposed to be spaced apart from each other along the first direction X. Accordingly, a space may be formed between the plurality of first partitions 333a.

The plurality of second partitions 333b may be disposed between the first support member 131 and the second support member 132 on the second area A2. For example, each of the plurality of second partitions 333b may extend along the second direction Y and may be disposed to be spaced apart from each other along the first direction X. Accordingly, a space may be formed between the plurality of second partitions 333b.

Further, each of the plurality of first partitions 333a and the plurality of second partitions 333b may have a rectangular shape on the side surface. For example, each of the plurality of first partitions 333a and the plurality of second partitions 333b may have a rectangular shape as seen from a plane defined by the first direction X and the third direction Z.

A height of the first partition 333a may be different from a height of the second partition 333b. For example, the height of the first partition 333a in the third direction Z may be smaller than the height of the second partition 333b in the third direction Z. For example, as described with reference to FIGS. 4A and 4B, a height of each of the plurality of second partitions 333b disposed on the second area A2 may be substantially equal to or smaller than the length of the space between the first support member 131 and the second support member 132 along the third direction Z. Further, the height of each of the plurality of first partitions 333a disposed on the first area A1 may be designed to have the smallest height which is available by the process.

As described above, the plurality of first partitions 333a may have a small height so that an emission angle of light which is incident to the first area A1 may not be substantially restricted. Accordingly, in the first area A1 in which the plurality of first partition 333a is disposed, the light may be provided in the second range which is larger than the first range.

Accordingly, in the case of an image which is displayed by light emitted from the first light source unit 110 disposed below the light controller 330, in the second area A2 of the active area AA overlapping an area in which the plurality of second partitions 333b is disposed, the image may be displayed at the second viewing angle, for example, at a narrow viewing angle. Further, in the first area A1 overlapping an area in which the plurality of first partitions 333a having a small height is disposed, the image may be displayed at the first viewing angle, for example, at a wide viewing angle.

Further, a partition may not be formed only in a partial area of the active area AA, but a plurality of partitions 333 may be formed in the entire active area AA, during the manufacturing process of the light controller 330, so that the manufacturing process of the light controller 330 is more simplified.

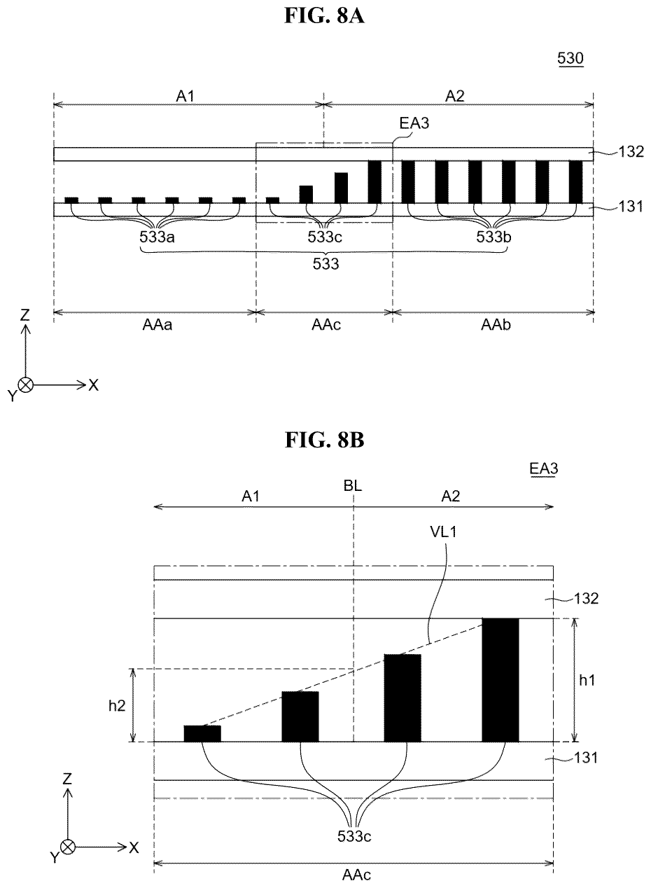

FIG. 7 is a schematic side view illustrating still another example of a light controller included in a display device of FIG. 2.

A light controller 430 illustrated in FIG. 7 may represent still another example of the light controller 130 included in the display device 100 which has been described with reference to FIG. 2.

Further, FIG. 7 may illustrate a modified embodiment of the embodiment of FIG. 5A with regard to an area in which a plurality of partitions 433 included in the light controller 430 is disposed. Accordingly, in FIG. 7, in order to avoid a redundant description, differences from the above-described embodiments will be mainly described.

Referring to FIGS. 2 and 7, the light controller 430 may include a first support member 131, a second support member 132 which is opposite to the first support member 131, and a plurality of partitions 433 disposed between the first support member 131 and the second support member 132. By doing this, the light controller may control a viewing angle or an emission angle of light which travels toward the third direction Z which is perpendicular to the active area AA, according to the first direction X.

The plurality of partitions 433 may be disposed on the entire active area AA. For example, the plurality of partitions 433 may include a plurality of first partitions 433a disposed on the first area A1 and a plurality of second partitions 433b disposed on the second area A2.

The plurality of first partitions 433a may be disposed between the first support member 131 and the second support member 132 on the first area A1. For example, each of the plurality of first partitions 433a may extend along the second direction Y and may be disposed to be spaced apart from each other along the first direction X. Accordingly, a space may be formed between the plurality of first partitions 433a.

The plurality of second partitions 433b may be disposed between the first support member 131 and the second support member 132 on the second area A2. For example, each of the plurality of second partitions 433b may extend along the second direction Y and may be disposed to be spaced apart from each other along the first direction X. Accordingly, a space may be formed between the plurality of second partitions 433b.

Further, each of the plurality of first partitions 433a and the plurality of second partitions 433b may have a trapezoidal shape on the side surface. For example, each of the plurality of first partitions 433a and the plurality of second partitions 433b may have a trapezoidal shape as seen from a plane defined by the first direction X and the third direction Z.

A height of the first partition 433a may be different from a height of the second partition 433b. For example, the height of the first partition 433a may be smaller than the height of the second partition 433b. For example, a height of each of the plurality of second partitions 433b disposed on the second area A2 may be substantially equal to or smaller than the length of the space between the first support member 131 and the second support member 132 along the third direction Z. Further, the height of each of the plurality of first partitions 433a disposed on the first area A1 may be designed to have the smallest height which is available by the process.

As described above, the plurality of first partitions 433a has a small height so that an emission angle of light which is incident to the first area A1 may not be substantially restricted. Accordingly, in the first area A1 in which the plurality of first partition 433a is disposed, the light may be provided in the second range which is larger than the first range.

Accordingly, in the case of an image which is displayed by light emitted from the first light source unit 110 disposed below the light controller 430, in the second area A2 of the active area AA overlapping an area in which the plurality of second partitions 433b is disposed, the image may be displayed at the second viewing angle, for example, at a narrow viewing angle. Further, in the first area A1 overlapping an area in which the plurality of first partitions 433a having a small height is disposed, the image may be displayed at the first viewing angle, for example, at a wide viewing angle.

Further, a partition may not be formed only in a partial area of the active area AA, but a plurality of partitions 433 may be formed on the entire active area AA, during the manufacturing process of the light controller 430 so that the manufacturing process of the light controller 430 may be more simplified.

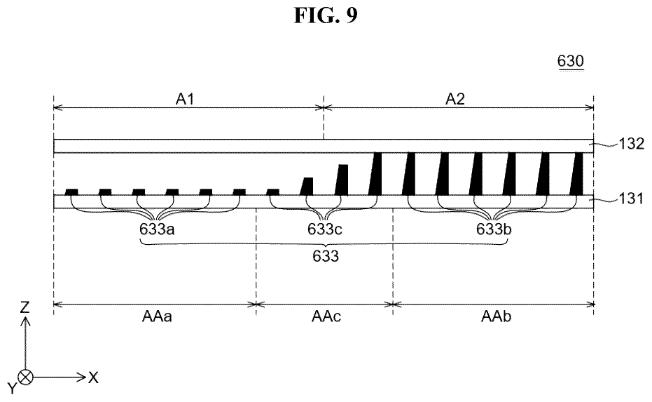

FIG. 8A is a schematic side view illustrating still another example of a light controller included in a display device of FIG. 2. FIG. 8B is an enlarged schematic view illustrating an example of a part EA3 of FIG. 8A.

A light controller 530 illustrated in FIG. 8A may represent another example of the light controller 130 included in the display device 100 which has been described with reference to FIG. 2.

Further, FIG. 8A may illustrate a modified embodiment of the embodiment of FIG. 6 with regard to a height of a plurality of partitions 533 included in the light controller 530. Accordingly, in FIGS. 8A and 8B, in order to avoid a redundant description, differences from the above-described embodiments will be mainly described.

Referring to FIGS. 2 and 8A, the light controller 530 may include a first support member 131, a second support member 132 which is opposite to the first support member 131, and a plurality of partitions 533 disposed between the first support member 131 and the second support member 132. By doing this, the light controller may control a viewing angle or an emission angle of light which travels toward the third direction Z which is perpendicular to the active area AA, according to the first direction X.

Referring to FIG. 8A, the active area AA may be divided into a plurality of sub areas. For example, the active area AA may be divided into a first sub area AAa, a second sub area AAb, and a third sub area AAc. Here, the first sub area AAa may correspond to a partial area of the first area A1, the second sub area AAb may correspond to a partial area of the second area A2, and the third sub area AAc may be an area which is disposed between the first sub area AAa and the second sub area AAb and may include a boundary disposed between the first area A1 and the second area A2. The third sub area AAc may be defined as an area including an area excluding the first sub area AAa from the first area A1 and an area excluding the second sub area AAb from the second area A2.

The plurality of partitions 533 may be disposed on the first sub area AAa, the second sub area AAb, and the third sub area AAc of the active area AA. For example, the plurality of partitions 533 may include a plurality of first partitions 533a disposed on the first sub area AAa, a plurality of second partitions 533b disposed on the second sub area AAb, and a plurality of third partitions 533c disposed on the third sub area AAc.

The plurality of first partitions 533a may be disposed between the first support member 131 and the second support member 132 on the first sub area AAa. For example, each of the plurality of first partitions 533a may extend along the second direction Y and may be disposed to be spaced apart from each other along the first direction X. Accordingly, a space may be formed between the plurality of first partitions 533a.

The plurality of second partitions 533b may be disposed between the first support member 131 and the second support member 132 on the second sub area AAb. For example, each of the plurality of second partitions 533b may extend along the second direction Y and may be disposed to be spaced apart from each other along the first direction X. Accordingly, a space may be formed between the plurality of second partitions 533b.

The plurality of third partitions 533c may be disposed between the first support member 131 and the second support member 132 on the third sub area AAc. For example, each of the plurality of third partitions 533c may extend along the second direction Y and may be disposed to be spaced apart from each other along the first direction X. Accordingly, a space may be formed between the plurality of third partitions 533c.

Further, each of the plurality of first partitions 533a, the plurality of second partitions 533b, and the plurality of third partitions 533c may have a rectangular shape on the side surface. For example, each of the plurality of first partitions 533a, the plurality of second partitions 533b, and the plurality of third partitions 533c may have a rectangular shape as seen from a plane defined by the first direction X and the third direction Z.

A height of the first partition 533a may be different from a height of the second partition 533b. For example, the height of the first partition 533a may be smaller than the height of the second partition 533b. For example, a height of each of the plurality of second partitions 533b disposed on the second sub area AAb may be substantially equal to the length of the space between the first support member 131 and the second support member 132 along the third direction Z (or thickness direction). Further, the height of each of the plurality of first partitions 533a disposed on the first sub area AAa may be designed to have the smallest height which is available by the process.

Further, the height of the plurality of third partitions 533c may be gradually increased toward the first direction X. For example, the height of the plurality of third partitions 533c may be gradually increased from the first area A1 or the first sub area AAa to the second area A2 or the second sub area AAb. For example, a third partition 533c, among the plurality of third partitions 533c, which is the most adjacent to the first sub area AAa, may have the same height as the first partition 533a. A third partition 533c, among the plurality of third partitions 533c, which is the most adjacent to the second sub area Aab, may have the same height as the second partition 533b. The remaining third partition 533c, among the plurality of third partitions 533c, may have a height between the first partition 533a and the second partition 533b and may be increased toward the first direction X.

In other words, the height of the plurality of partitions 533 may gradually be increased from the vicinity of the boundary between the first area A1 and the second area A2 toward the first direction X, in particular, toward the second sub area AAb. Accordingly, in the case of the image which is displayed by light which is incident to the light controller 530, a boundary visibility according to a viewing angle difference of the first area A1 and the second area A2 may be minimized in the boundary between the second area A2 and the first area A1.

In the second area A2, a viewing angle is entirely restricted to display an image at a second viewing angle, for example, a narrow viewing angle and in the first area A1, the viewing angle may not be substantially restricted to display an image at a first viewing angle, for example, a wide viewing angle.

The boundary between the first area A1 and the second area A2 of the active area AA may be defined in the third sub area AAc. To be more specific, further referring to FIG. 8B, on a first virtual line VL1 connecting center points of top surfaces of the plurality of third partitions 533c, a straight line parallel to the third direction Z, with respect to a point where a height from the first support member 131 is a second height h2 which is half the first height h1 which is the height of the second partition 553b disposed on the second area A2, may be defined as the boundary line BL between the first area A1 and the second area A2. However, it is merely illustrative that the first area A1 and the second area A2 are divided in the active area AA along the boundary line BL and the first area A1 and the second area A2 in the active area AA may be defined in various ways based on the design. For example, based on the design, on the first virtual line VL1 connecting center points of top surfaces of the plurality of third partitions 533c, a straight line parallel to the third direction Z based on a point having a height equal to ⅔ of the first height h1 may be defined as the boundary line BL between the first area A1 and the second area A2.

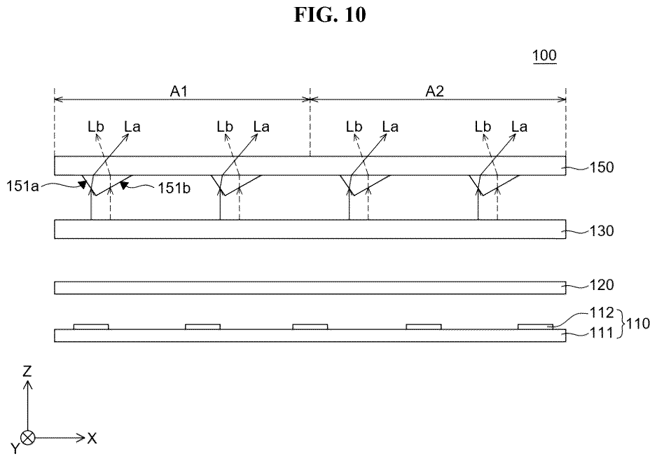

FIG. 9 is a schematic side view illustrating still another example of a light controller included in a display device of FIG. 2.

A light controller 630 illustrated in FIG. 9 may represent still another example of the light controller 130 included in the display device 100 which has been described with reference to FIG. 2.

Further, FIG. 9 may illustrate a modified embodiment of the embodiment of FIG. 7 with regard to a height of a plurality of partitions 633 included in the light controller 630.

Accordingly, in FIG. 9, in order to avoid a redundant description, differences from the above-described embodiments will be mainly described.

Referring to FIGS. 2 and 9, the light controller 630 may include a first support member 131, a second support member 132 which is opposite to the first support member 131, and a plurality of partitions 633 disposed between the first support member 131 and the second support member 132. By doing this, the light controller may control a viewing angle or an emission angle of light which travels toward the third direction Z which is perpendicular to the active area AA, according to the first direction X.

Referring to FIG. 9, the active area AA may be divided into a plurality of sub areas. Here, the plurality of sub areas, in particular, the area division of the first sub area AAa, the second sub area AAb, and the third sub area AAc may be substantially the same as or similar to the area division which has been described with reference to FIG. 8A so that a redundant description will not be repeated.

The plurality of partitions 633 may be disposed on the active area AA. For example, the plurality of partitions 633 may include a plurality of first partitions 633a disposed on the first sub area AAa, a plurality of second partitions 633b disposed on the second sub area AAb, and a plurality of third partitions 633c disposed on the third sub area AAc.

The plurality of first partitions 633a may be disposed between the first support member 131 and the second support member 132 on the first sub area AAa. For example, each of the plurality of first partitions 633a may extend along the second direction Y and may be disposed to be spaced apart from each other along the first direction X. Accordingly, a space may be formed between the plurality of first partitions 633a.

The plurality of second partitions 633b may be disposed between the first support member 131 and the second support member 132 on the second sub area AAb. For example, each of the plurality of second partitions 633b may extend along the second direction Y and may be disposed to be spaced apart from each other along the first direction X. Accordingly, a space may be formed between the plurality of second partitions 633b.

The plurality of third partitions 633c may be disposed between the first support member 131 and the second support member 132 on the third sub area AAc. For example, each of the plurality of third partitions 633c may extend along the second direction Y and may be disposed to be spaced apart from each other along the first direction X. Accordingly, a space may be formed between the plurality of third partitions 633c.

Further, each of the plurality of first partitions 633a, the plurality of second partitions 633b, and the plurality of third partitions 633c may have a trapezoidal shape on the side surface. For example, each of the plurality of first partitions 633a, the plurality of second partitions 633b, and the plurality of third partitions 633c may have a trapezoidal shape as seen from a plane defined by the first direction X and the third direction Z.

A height of the first partition 633a may be different from a height of the second partition 633b. For example, the height of the first partition 633a may be smaller than the height of the second partition 633b. For example, a height of each of the plurality of second partitions 633b disposed on the second sub area AAb is substantially equal to the length of the space between the first support member 131 and the second support member 132 along the third direction Z. Further, the height of each of the plurality of first partitions 633a disposed on the first sub area AAa may be designed to have the smallest height which is available by the process.

Further, the height of the plurality of third partitions 633c may be gradually decreased toward the opposite direction to the first direction X. For example, a third partition 633c which is the most adjacent to the second sub area AAb, among the plurality of third partitions 633c, has the same height as the second partition 633b. A third partition 633c which is the most adjacent to the first sub area AAa, among the plurality of third partitions 633c, has the same height as the first partition 633a. The remaining third partition 633c, among the plurality of third partitions 633c, has a height between the first partition 633a and the second partition 633b and is decreased toward the opposite direction to the first direction X.

Accordingly, in the case of the image displayed by light which is incident to the light controller 630, the boundary visibility according to the viewing angle difference of the first area A1 and the second area A2 in the boundary portion between the first area A1 and the second area A2 may be minimized.

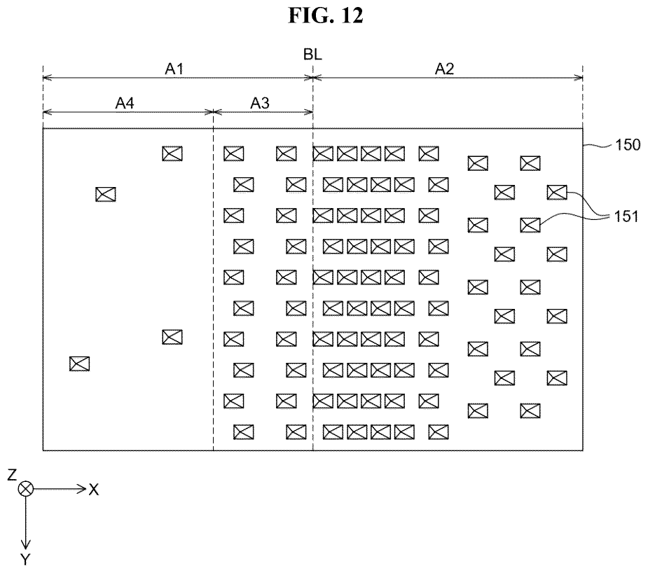

FIG. 10 is a schematic side view of a display device according to an embodiment of the present disclosure. FIG. 11 is a schematic view illustrating an example of a first protruding pattern included in a light guide plate of a display device of FIG. 10. In FIG. 10, for the convenience of description, among the plurality of first protruding patterns 151, only two first protruding patterns 151 disposed in the first area A1 and two first protruding patterns 151 disposed in the second area A2 are illustrated.

Referring to FIG. 10, the plurality of first protruding patterns 151 may be disposed on a lower surface of the light guide plate 150. For example, plurality of first protruding patterns 151 may be formed to protrude in a lower direction of the light guide plate 150, for example, in an opposite direction of the third direction Z.

Each of the plurality of first protruding patterns 151 may have a quadrangular pyramid shape or a square pyramid shape. For example, referring to FIG. 11, each of the plurality of first protruding patterns 151 may have four inclined surfaces which form a predetermined angle with a lower surface of the light guide plate 150, in particular, a plane defined by the first direction X and the second direction Y and have a triangular shape. For example, each of the plurality of first protruding patterns 151 may include a first inclined surface 151a, a second inclined surface 151b which is disposed opposite to the first inclined surface 151a, a third inclined surface 151c, and a fourth inclined surface 151d which is disposed opposite to the third inclined surface 151c. For example, the second inclined surface 151b may be disposed to be opposite to the first inclined surface 151a and may be disposed on one side of the first inclined surface 151a along the first direction X. The third inclined surface 151c may share a first side S1 with the first inclined surface 151a and may share a second side S2 with the second inclined surface 151b and may be disposed on a side along an opposite direction of the second direction Y of the first inclined surface 151a and the second inclined surface 151b. The fourth inclined surface 151d may share a third side S3 with the first inclined surface 151a, may share a fourth side S4 with the second inclined surface 151b, and may be disposed to be opposite to the third inclined surface 151c and may be disposed on a side along a second direction Y of the third inclined surface 151c. The first inclined surface 151a, the second inclined surface 151b, the third inclined surface 151c, and the fourth inclined surface 151d of each of the plurality of first protruding patterns 151 may share one vertex VT. Here, the vertex VT may correspond to a vertex of the first protruding pattern 151 having a quadrangular pyramid shape or a square pyramid shape and the first side S1, the second side S2, the third side S3, and the fourth side S4 may mean four edges connected to the vertex VT of the first protruding pattern 151 having a quadrangular pyramid shape or a square pyramid shape.

The quadrangular pyramid shape or the square pyramid shape of each of the plurality of first protruding patterns 151 may have an asymmetric shape. For example, the vertex VT of the quadrangular pyramid or square pyramid shape included in each of the plurality of first protruding patterns 151 may be formed to be biased toward the first area A1 which is an opposite direction of the first direction X. Accordingly, an angle formed by the first inclined surface 151a of each of the plurality of first protruding patterns 151 and the light guide plate 150 may be larger than an angle formed by the second inclined surface 151b and the light guide plate 150, and an area of the second inclined surface 151b may be larger than an area of the first inclined surface 151a.

The third inclined surface 151c and the fourth inclined surface 151d of each of the plurality of first protruding patterns 151 may be symmetric with respect to a second virtual line VL2 which passes through the vertex VT and is parallel to the first direction X. Accordingly, an angle formed by the third inclined surface 151c of each of the plurality of first protruding patterns 151 and the light guide plate 150 may be equal to an angle formed by the fourth inclined surface 151d and the light guide plate 150, and an area of the third inclined surface 151c may be equal to an area of the fourth inclined surface 151d.

As described above, a path of light which is incident to the light guide plate 150 may be controlled by the plurality of first protruding patterns 151 which is formed on the lower surface of the light guide plate 150 and has an asymmetric quadrangular pyramid or square pyramid shape.

To be more specific, the plurality of first protruding patterns 151 may control a viewing angle of light which is emitted from the second light source unit 140 disposed on a side portion of the light guide plate 150 to be incident to the side surface of the light guide plate 150 and be emitted to the upper surface of the light guide plate 150.

For example, each of the plurality of first protruding patterns 151 may have an asymmetric quadrangular pyramid or square pyramid shape so that the vertex VT of the first protruding pattern 151 is formed to be biased to the first area A1 which is an opposite direction of the first direction X. Accordingly, the plurality of first protruding patterns 151 may shift a profile of light which is incident to the side surface of the light guide plate 150 to the first area A1 which is an opposite direction of the first direction X. Here, as described above, in the first mode, the second light source unit 140 may emit light so that an image is displayed in the second area A2 at the first viewing angle, in particular, the wide viewing angle. At this time, a profile of light which is emitted from the second light source unit 140 disposed on the side portion of the light guide plate 150 to be incident to the side surface of the light guide plate 150 and be emitted to the upper surface of the light guide plate 150 is shifted to the first area A1 by the plurality of first protruding patterns 151 formed on the lower surface of the light guide plate 150.

Therefore, in the first mode, the viewing angle of the first area A1 of the image displayed in the second area A2 may be increased. Accordingly, a viewing angle of the image with the first viewing angle which is displayed on the second area A2, in particular, the image with a wide viewing angle, may be improved by light emitted from the second light source unit 140 in the first mode.

Further, the plurality of first protruding patterns 151 may control a viewing angle of light which is emitted from the first light source unit 110 disposed below the light guide plate 150, for example, on the bottom of the display device 100 to be incident to the lower surface of the light guide plate 150 and be emitted to the upper surface of the light guide plate 150.

For example, each of the plurality of first protruding patterns 151 may have an asymmetric quadrangular pyramid or square pyramid shape so that as described above, the first inclined surface 151a and the second inclined surface 151b of each first protruding pattern 151 form a predetermined angle with the lower surface of the light guide plate 150, for example, a surface defined by the first direction X and the second direction Y. Further, an inclination angle of the first inclined surface 151a may be formed to be larger than an inclination angle of the second inclined surface 151b. Therefore, the plurality of first protruding patterns 151 may condense light which is incident to the lower surface of the light guide plate 150 and shifts the profile of the light to the second area A2 which is directed to the first direction X.

To be more specific, further referring to FIG. 10, according to an inclination angle difference of the first inclined surface 151a and the second inclined surface 151b, an angle at which light La incident to the first inclined surface 151a included in each of the plurality of first protruding patterns 151 is refracted to the first direction X by the first protruding pattern 151 may be larger than an angle at which light Lb incident to the second inclined surface 151b is refracted to the opposite direction of the first direction X by the first protruding pattern 151.

Therefore, the light which is provided from the bottom of the light guide plate 150 may be shifted (or entirely shifted) to the second area A2. Here, as described above, in the second mode, the first light source unit 110 may emit light so that an image is displayed in the second area A2 at the second viewing angle, in particular, the narrow viewing angle. At this time, light which is emitted from the first light source unit 110 disposed below the light guide plate 150 to be incident to the lower surface of the light guide plate 150 and be emitted to the upper surface of the light guide plate 150 may be condensed to the upper direction, in particular, to the third direction Z (or thickness direction) by the plurality of first protruding patterns 151 formed on the lower surface of the light guide plate 150. Further, the profile of the light may be shifted to the second area A2. Therefore, in the second mode, the viewing angle of the image displayed in the second area A2 may be more effectively controlled. Accordingly, a viewing angle of the image with the second viewing angle which is displayed on the second area A2, in particular, the image with a narrow viewing angle, may be more effectively controlled by light emitted from the first light source unit 110 in the second mode.

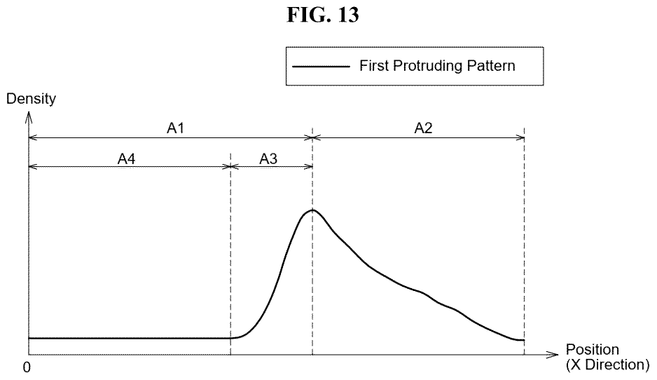

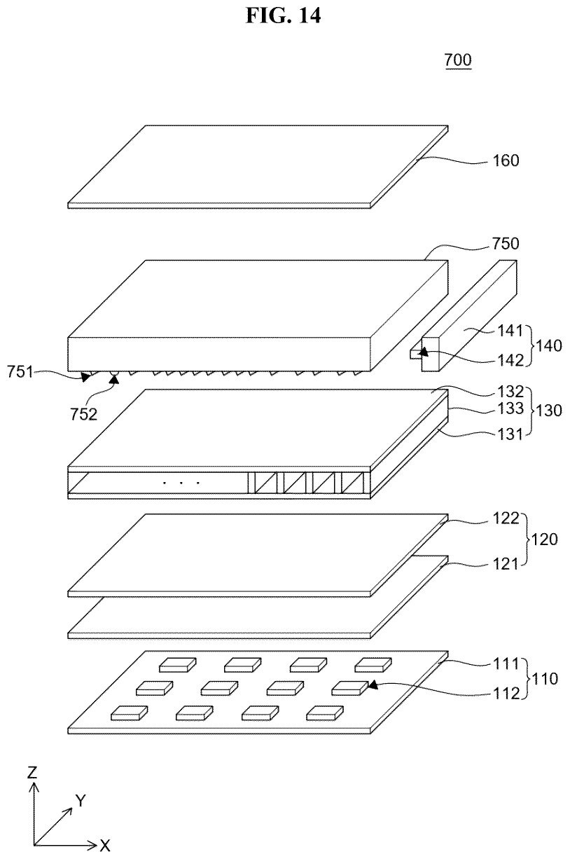

FIG. 12 is a schematic rear view illustrating an example of a light guide plate included in a display device of FIG. 10. FIG. 13 is a schematic graph for explaining an example of a placement density of a first protruding pattern included in a light guide plate of FIG. 12.

A graph for a placement density of the first protruding pattern 151 according to a position in the first direction X is illustrated by the solid line in FIG. 13.

Referring to FIGS. 12 and 13, the plurality of first protruding patterns 151 may be disposed on the lower surface of the light guide plate 150 with a different density in each area.

In the present disclosure, the density with which the first protruding patterns 151 are disposed may be defined as a percentage (%) of an area in which the first protruding patterns 151 are disposed with respect to the entire area of the unit area.

The plurality of first protruding patterns 151 may be disposed in the first area A1 with a first density, and may be disposed in the second area A2 with a second density which is higher than the first density. Further, the farther from the boundary line BL of the first area Al and the second area A2, for example, the farther from the boundary line BL in the first direction X and/or the opposite direction of the first direction X, the lower the placement density of the first protruding patterns 151.

To be more specific, as described above, the plurality of first protruding patterns 151 may be formed on the lower surface of the light guide plate 150 so that a profile of light which is emitted from the second light source unit 140 to be incident to the side surface of the light guide plate 150 is shifted to the first area A1 which is an opposite direction of the first direction X to be emitted to the upper surface of the light guide plate 150. Further, a profile of light which is emitted from the first light source unit 110 to be incident to the lower surface of the light guide plate 150 may be shifted to the second area A2 which is directed to the first direction X to be emitted to the upper surface of the light guide plate 150. Here, in the first mode, the image displayed on the second area A2 by the light emitted from the second light source unit 140 may be displayed at the first viewing angle, in particular, a wide viewing angle, and in the second mode, the image displayed on the second area A2 by the light emitted from the first light source unit 110 may be displayed at the second viewing angle, in particular, a narrow viewing angle. Therefore, the larger the number of the plurality of first protruding patterns 151 disposed on the second area A2, the larger the viewing angle of the image displayed on the second area A2 in the first mode. Further, the viewing angle in the second mode may be more effectively controlled. Accordingly, in the second area A2, the first protruding patterns 151 may need to be placed as much as possible so that in the second area A2, the first protruding patterns 151 may be disposed with the second density which is higher than the first density with which the first protruding patterns 151 are disposed in the first area A1.

However, light which is emitted from the second light source unit 140 to be provided to the light guide plate 150 may be reflected (or totally reflected) to the first area A1 in the light guide plate 150 while traveling in the light guide plate 150. As described above, the first protruding pattern 151 may guide light which is incident to the side surface of the light guide plate 150 to the third direction Z which is an upward direction. Therefore, when the placement density of the first protruding patterns 151 disposed in an area of the second area A2 which is adjacent to the second light source unit 140 is too high, an amount of light which is provided to the first area A1 in the light guide plate 150 may be reduced, which causes the luminance degradation in the first area A1.

Accordingly, the plurality of first protruding patterns 151 disposed on the second area A2 may be disposed with a relatively low density in an area adjacent to the second light source unit 140 and may be disposed with a relatively high density in an area far from the second light source unit 140, for example, in an area adjacent to the boundary line BL between the first area A1 and the second area A2. For example, the placement density of the plurality of first protruding patterns 151 disposed on the second area A2 may be reduced as the distance from the boundary line BL between the first area A1 and the second area A2 approaches the first direction X, which is directed to the second light source unit 140. According to the placement density of the first protruding patterns 151, the viewing angle in each driving mode may be more effectively controlled and the reduction in the amount of light which is provided to the first area A1 in the light guide plate 150 is minimized to suppress the luminance degradation in the first area A1.

Further, the first protruding pattern 151 may condense light which is supplied to the light guide plate 150, for example, light which is emitted from the first light source unit 110 disposed below the light guide plate 150 to be provided to the light guide plate 150 to guide the light to the third direction Z. An image which is displayed in the first area A1 may be displayed at a first viewing angle, in particular, a wide viewing angle regardless of the driving mode so that there may be a problem in that the larger the number of the plurality of first protruding patterns 151 disposed on the first area A1, the narrower the viewing angle of the image displayed on the first area A1. Therefore, it is necessary to place the first protruding pattern 151 as small as possible in the first area A1.

However, when the first protruding pattern 151 is not disposed in the first area A1, there may be a problem in that the boundary between the first area A1 and the second area A2 in which the first protruding pattern 151 is disposed is visible. Particularly, as described above, in an area of the second area A2 which is adjacent to the boundary line BL, the placement density of the first protruding pattern 151 may be the highest so that when the first protruding pattern 151 is not disposed in the first area A1, the boundary visibility may be increased.

Accordingly, the plurality of first protruding patterns 151 disposed on the first area A1 may be disposed with a relatively high density in the second area A2, in particular, an area adjacent to the boundary line BL and may be disposed with a relatively low density in an area far from the boundary line BL. For example, the farther from the boundary line BL between the first area A1 and the second area A2, in particular, the closer to the opposite direction of the first direction X, the lower the placement density of the plurality of first protruding patterns 151 disposed on the first area A1. For example, in a third area A3 of the first area A1 adjacent to the second area A2, the placement density of the first protruding pattern 151 may be reduced toward the opposite direction of the first direction X. In a fourth area A4 of the first area A1 which is adjacent to the third area A3 in the opposite direction of the first direction X, the placement density of the first protruding pattern 151 may have a lowest value, and the first protruding pattern 151 may be disposed with a constant density. In the present disclosure, the third area A3 may indicate a partial area of the first area A1 which is adjacent to the second area A2, and the fourth area A4 may be an area of the first area A1 excluding the third area A3 and indicate the most area of the first area A1. However, it is just illustrative and the division of the first area A1 may be defined in various ways based on the design. According to the placement density of the first protruding pattern 151 as described above, the problem in that the viewing angle of the image displayed on the first area A1 is narrowed may be suppressed and the boundary visibility between the first area A1 and the second area A2 may be minimized.

According to the embodiment, as illustrated in FIG. 13, the degree to which the placement density of the first protruding pattern 151 disposed in the second area A2 may be reduced as it is farther from the boundary line BL. For example, an absolute value of the gradient of the placement density of the first protruding pattern 151 disposed in the second area A2 may be smaller than the degree to which the placement density of the first protruding pattern 151 disposed in the third area A3 is reduced as it is farther from the boundary line BL, for example, an absolute value of the gradient of the placement density of the first protruding pattern 151 disposed in the third area A3. In particular, with regard to the degree to which the placement density of the first protruding pattern 151 is reduced as it is farther from the boundary line BL, the placement density of the first protruding pattern 151 may be reduced (or gently reduced) in the second area A2 more than in the first area A1, for example, the third area A3.

It has been described above that the first protruding pattern 151 is disposed in the fourth area A4 with the lowest density, but it is just illustrative, but is not limited thereto. For example, the first protruding pattern 151 may be disposed only in the third area A3 of the first area A1 adjacent to the second area A2, but is not disposed in the fourth area A4.

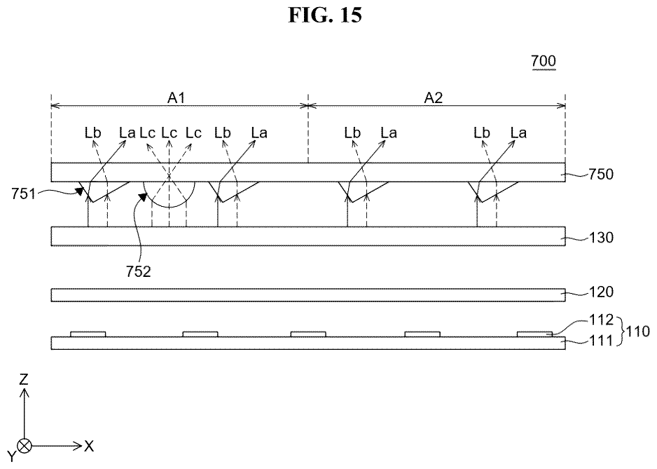

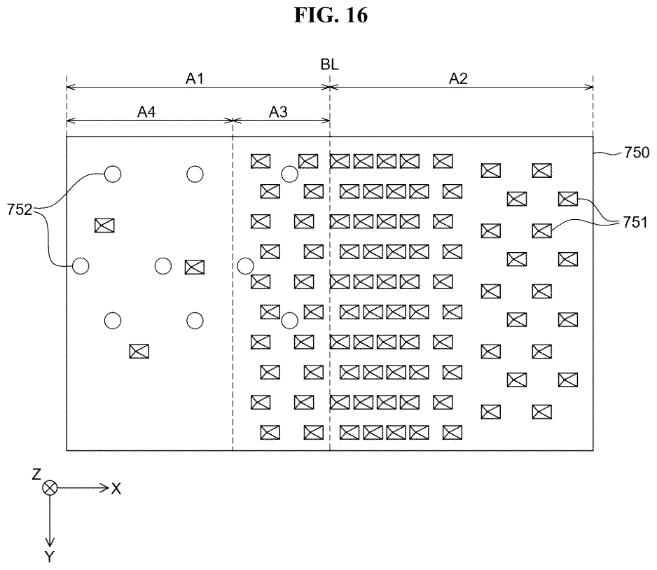

FIG. 14 is an exploded schematic perspective view of a display device according to another embodiment of the present disclosure. FIG. 15 is a schematic side view of a display device according to another embodiment of the present disclosure. In FIG. 15, for the convenience of description, among the plurality of first protruding patterns 151, only two first protruding patterns 151 disposed in the first area A1 and two first protruding patterns 151 disposed in the second area A2 are illustrated and only a second protruding pattern 752 disposed in the first area A1, among a plurality of second protruding patterns 752 is illustrated.

FIG. 14 may illustrate a modified embodiment of the embodiment of FIG. 2 with regard to the plurality of second protruding patterns 752 included in a light guide plate 750.

Accordingly, in FIGS. 14 and 15, in order to avoid a redundant description, differences from the above-described embodiments will be mainly described.

Referring to FIG. 14, the light guide plate 750 included in a display device 700 according to another embodiment of the present disclosure may include a plurality of first protruding patterns 751 and a plurality of second protruding patterns 752 disposed on a bottom surface of the light guide plate 750. For example, each of the plurality of first protruding patterns 751 and each of the plurality of second protruding patterns 752 may be formed as a relief which protrudes downward from the lower surface of the light guide plate 750, for example, in an opposite direction of the third direction Z (or thickness direction).

The plurality of first protruding patterns 751 and the plurality of second protruding patterns 752 may be disposed so as not to overlap each other, but are not limited thereto.

Each of the plurality of first protruding patterns 751 and each of the plurality of second protruding patterns 752 may include a material having a refractive index which is different from that of air, for example, a refractive index which is higher than the refractive index of air. For example, each of the plurality of first protruding patterns 751 and each of the plurality of second protruding patterns 752 include the same material as the light guide plate 750 to have the same refractive index as the light guide plate 750, but are not limited thereto.

Each of the plurality of first protruding patterns 751 may have an asymmetric quadrangular pyramid or square pyramid shape and may be disposed on the lower surface of the light guide plate 750 with a different density in each area. For example, the plurality of first protruding patterns 751 may have substantially equal shape or similar shape to the plurality of first protruding patterns 151 included in the display device 100 according to the embodiment of the present disclosure which has been described with reference to FIGS. 2 and 10, 11, 12, and 13, and may be disposed with substantially equal or similar density to the placement density of the first protruding pattern 151. Therefore, a redundant description will not be repeated.

Each of the plurality of second protruding patterns 752 may have a hemispherical shape which protrudes from the lower surface of the light guide plate 750. For example, each of the plurality of second protruding patterns 752 may be a dot pattern, but is not limited thereto.

Further, the plurality of second protruding patterns 752 may be disposed only in a partial area of the active area AA. For example, the plurality of second protruding patterns 752 may be disposed on the first area A1 and may not be disposed on the second area A2.

A path of light which is incident to the light guide plate 750, for example, a path of the light on the first area A1 may be controlled by the plurality of second protruding patterns 752 as described above.

To be more specific, even though the plurality of first protruding patterns 751 is disposed with a minimum density as described above, the plurality of first protruding patterns 751 may be disposed (or partially disposed) on the first area A1 with a minimum placement density. Further, the plurality of first protruding patterns 751 may be disposed on the second area A2. The first protruding pattern 751 may condense light which is provided to the light guide plate 750, for example, light which is emitted from the first light source unit 110 disposed below the light guide plate 750 to be provided to the light guide plate 750 to be guided to the third direction Z. Therefore, there may be a problem in that a viewing angle in the first area Al in which the image is displayed at a first viewing angle, in particular, a wide viewing angle regardless of the driving mode is narrowed.

Here, each of the plurality of second protruding patterns 752 may have a hemispherical shape to diffuse light which is provided to the light guide plate 750. For example, light which is emitted from the first light source unit 110 disposed below the light guide plate 750 to be provided to the light guide plate 750 to suppress the problem in that the viewing angle of the image which is displayed at the first viewing angle in the first area A1 may be narrowed.

For example, referring to FIG. 15, light Lc which is incident to each of the plurality of second protruding patterns 752 may be refracted from an incident surface of the second protruding pattern 752 by the second protruding pattern 752 having a hemispherical shape to be diffused on a plane defined by for example, the first direction X and the second direction Y to travel to the third direction Z, in particular, an upward direction. Therefore, the problem in that the viewing angle of the image which is displayed at the first viewing angle in the first area A1 may be narrowed by the first protruding pattern 751 may be cancelled by the second protruding pattern 752.

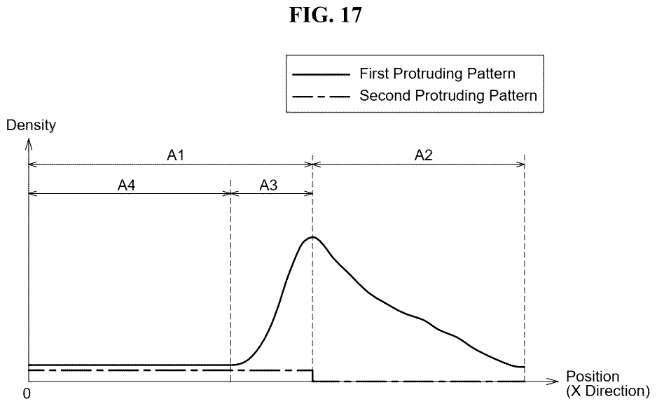

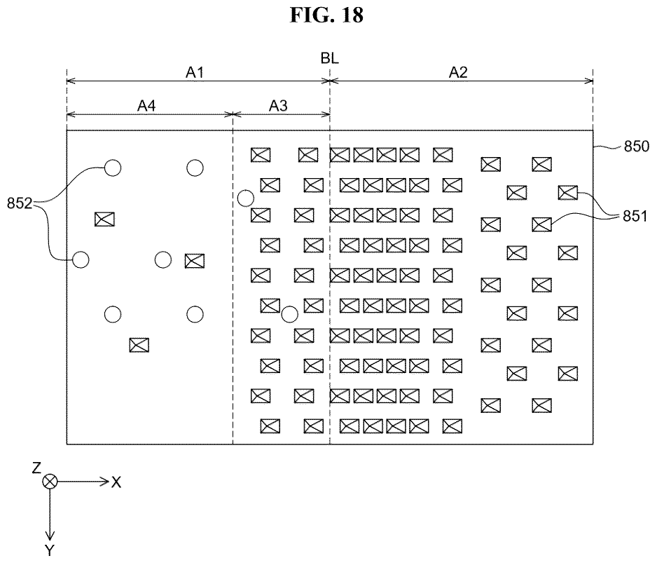

FIG. 16 is a schematic rear view illustrating an example of a light guide plate included in a display device of FIG. 15. FIG. 17 is a schematic graph for explaining an example of a placement density of a first protruding pattern and a second protruding pattern included in a light guide plate of FIG. 16.

In FIG. 17, a graph for a placement density of the first protruding pattern 751 according to a position in the first direction X may be illustrated by a solid line and a graph for a placement density of the second protruding pattern 752 according to a position in the first direction X is illustrated by a one-dot chain line.

In FIGS. 16 and 17, the placement relationship of the first protruding pattern 751 included in the light guide plate 750 may be substantially equal to or similar to the placement relationship of the first protruding pattern 151 included in the light guide plate 150 which has been described with reference to FIGS. 12 and 13 so that a redundant description will not be repeated.

Referring to FIGS. 16 and 17, the plurality of second protruding patterns 752 may be disposed on the lower surface of the light guide plate 750.

The plurality of second protruding patterns 752 may be disposed only in the first area A1 and may not be disposed in the second area A2.

Particularly, the plurality of second protruding patterns 752 disposed on the first area A1 may diffuse light which is emitted from the first light source unit 110 to be incident to the lower surface of the light guide plate 750 to be guided to the third direction Z, in particular, to the upward direction. Therefore, the problem in that the viewing angle of an image which is displayed at the first viewing angle in the first area A1 is narrowed by the first protruding pattern 751 disposed on the first area A1 may be cancelled.

The plurality of second protruding patterns 752 may be disposed on the first area A1 with a constant density. For example, as illustrated in FIG. 17, the placement density of the plurality of second protruding patterns 752 disposed on the first area A1 may be lower than a minimum value of the placement density of the plurality of first protruding patterns 751 disposed on the first area A1. For example, a ratio of a minimum value of the placement density of the plurality of first protruding patterns 751 disposed on the first area A1, for example, the placement density of the plurality of first protruding patterns 751 disposed on the fourth area A4 and a placement density of the plurality of second protruding patterns 752 disposed on the first area A1 may be about 4:3.

However, it is just illustrative so that the embodiment of the present disclosure is not limited thereto. For example, the placement density of the plurality of second protruding patterns 752 is substantially the same as or larger than the minimum value of the placement density of the plurality of first protruding patterns 751 disposed on the first area A1.

Further, the first protruding pattern 751 disposed on the second area A2 of the light guide plate 750 as described above may control a profile of light which is emitted from the first light source unit 110 to be incident to the lower surface of the light guide plate 750 to control the viewing angle of the image displayed on the second area A2 in the second mode to be narrow. Here, when the second protruding pattern 752 is disposed on the second area A2 in which the viewing angle is controlled according to the driving mode, the light which is emitted from the first light source unit 110 by the second protruding pattern 752 to be incident to the lower surface of the light guide plate 750 may be diffused to increase the viewing angle or the emission angle in the second area A2. Here, there may be a problem in that the image is displayed at a viewing angle which is larger than the second viewing angle set in the second area A2 in the second mode so that the plurality of second protruding patterns 752 is disposed only in the first area A1, but may not be disposed in the second area A2.

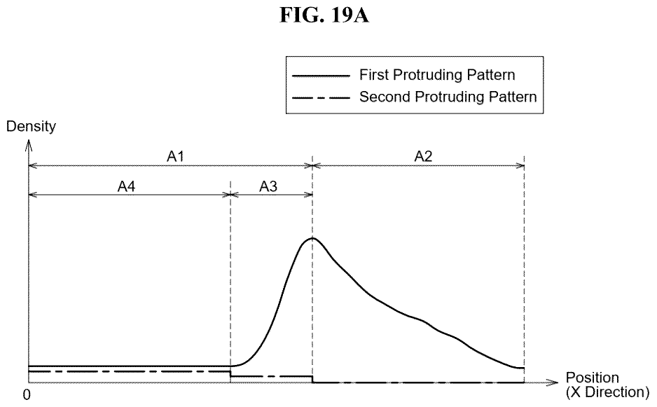

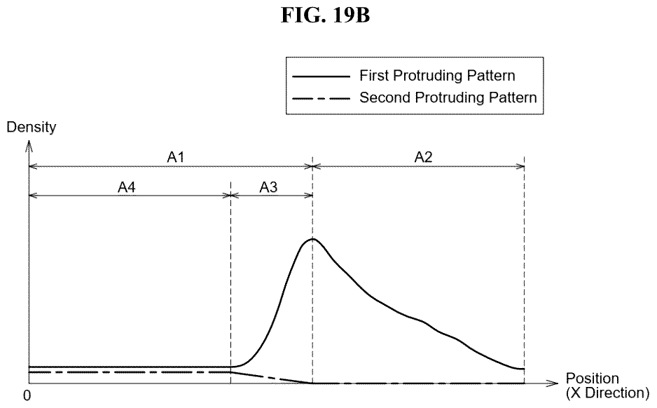

FIG. 18 is a schematic rear view illustrating another example of a light guide plate included in a display device of FIG. 15. FIGS. 19A and 19B are schematic graphs for explaining an example of a placement density of a first protruding pattern and a second protruding pattern included in a light guide plate of FIG. 18.

FIGS. 18, 19A, and 19B may illustrate a modified embodiment of the embodiment of FIGS. 16 and 17 with regard to a placement density of a plurality of second protruding patterns 852 included in a light guide plate 850. Accordingly, in FIGS. 18, 19A, and to 19B, in order to avoid a redundant description, differences from the above-described embodiments will be mainly described.

Referring to FIG. 18, the plurality of second protruding patterns 852 may be disposed only in a partial area of the active area AA. For example, the plurality of second protruding patterns 852 may be disposed on the first area A1 and may not be disposed on the second area A2.

Further, the plurality of second protruding patterns 852 disposed on the first area A1 may be disposed on the lower surface of the light guide plate 850 with a different density in each area.

For example, referring to FIG. 19A, the plurality of second protruding patterns 852 may be disposed on the third area A3 of the first area A1 adjacent to the second area A2 with a third density and may be disposed on the fourth area A4 of the first area A1 which is adjacent to the third area A3 in an opposite direction of the first direction X with a fourth density which is higher than the third density.

To be more specific, as described above, the plurality of second protruding patterns 852 may be formed to diffuse light which is emitted from the first light source unit 110 to be incident to the lower surface of the light guide plate 850 on the first area A1 to increase a viewing angle of the image displayed on the first area A1. The farther from the boundary line BL between the first area A1 and the second area A2, the more significant the viewing angle problem of the first area A1 which is caused by the problem in that the emission angle of light emitted from the light guide plate 850 in the first area A1 may be narrowed. Accordingly, the plurality of second protruding patterns 852 may be disposed with a higher density in an area of the first area A1 adjacent to the second area A2, for example, in the fourth area A4 which is farther than the third area A3. Accordingly, the viewing angle in the first area A1 may be more effectively improved.

According to the embodiment, the plurality of second protruding patterns 852 may be disposed with a constant density on each of the third area A3 and the fourth area A4.

For example, the placement density of the plurality of second protruding patterns 852 disposed on the third area A3 and the placement density of the plurality of second protruding patterns 852 disposed on the fourth area A4 may be lower than a minimum value of the placement density of the plurality of first protruding patterns 851 disposed on the first area A1, for example, the placement density of the plurality of first protruding patterns 851 disposed on the fourth area A4. For example, a ratio of the placement density of the plurality of first protruding patterns 851 disposed on the fourth area A4 and the placement density of the plurality of second protruding patterns 852 disposed on the fourth area A4 may be about 4:3. A ratio of the placement density of the plurality of first protruding patterns 851 disposed on the fourth area A4 and the placement density of the plurality of second protruding patterns 852 disposed on the third area A3 may be about 4:1 or about 2:1.

However, it is just illustrative so that the embodiment of the present disclosure is not limited thereto. For example, further referring to FIG. 19B, the placement density of the plurality of second protruding patterns 852 disposed on the third area A3 may be gradually reduced toward the first direction X, in particular, toward the second area A2. For example, the boundary visibility based on whether to place the second protruding pattern 852 between the first area A1 and the second area A2 may be minimized.

The embodiments of the present disclosure can also be described as follows.

According to an aspect of the present disclosure, a display device may include a first light source unit including a plurality of first light sources, a light controller which is disposed on the first light source unit and includes a plurality of partitions overlapping at least a partial area of the active area, a second light source unit which is disposed on the light controller and includes a plurality of second light sources, a light guide plate which is disposed to be parallel to the second light source unit and guides light provided from the second light source unit, and a display panel which is disposed on the light guide plate and displays an image using light provided from the first light source unit or the second light source unit, and the light guide plate may include a plurality of first protruding patterns which protrudes from a lower surface and is disposed with a different density in each area.

The active area may include a first area in which an image is displayed at a first viewing angle in a first mode and a second mode; and a second area which is adjacent to the first area in a first direction, and in the second area, an image may be displayed at the first viewing angle in the first mode, and an image may be displayed at a second viewing angle which is smaller than the first viewing angle in the second mode.

The plurality of first protruding patterns may be disposed with a first density in the first area and may be disposed with a second density which is higher than the first density in the second area.

A placement density of the plurality of first protruding patterns may be reduced as it is farther from a boundary between the first area and the second area.

The placement density of the plurality of first protruding patterns may be reduced in a third area of the first area which is adjacent to the second area as it is farther from the boundary between the first area and the second area, and the plurality of first protruding patterns may be disposed with a constant density in a fourth area of the first area which is adjacent to the third area in an opposite direction of the first direction.

A placement density of a first protruding pattern disposed on the second area, among the plurality of first protruding patterns, may be reduced toward the first direction, and the second light source unit may be disposed in a side of the light guide plate in the first direction.

The light guide plate further may include a plurality of second protruding patterns which protrudes from a lower surface and may have a shape different from that of the plurality of first protruding patterns.

The plurality of second protruding patterns may be disposed in the first area, but may not be disposed in the second area.

In the first area, the plurality of second protruding patterns may be disposed with a constant density.

A placement density of the plurality of second protruding patterns disposed in the first area may be smaller than a minimum value of a placement density of the plurality of first protruding patterns disposed in the first area.

The plurality of second protruding patterns may be disposed with a third density in a third area of the first area which is adjacent to the second area and may be disposed with a fourth density which is higher than the third density in a fourth area of the first area which is adjacent to the third area in an opposite direction of the first direction.

The plurality of second protruding patterns may be disposed with a constant density in each of the third area and the fourth area.

In the third area, a placement density of the plurality of second protruding patterns may be increased as it is farther from a boundary between the first area and the second area, and in the fourth area, the plurality of second protruding patterns may be disposed with a constant density.

Each of the plurality of first protruding patterns may have an asymmetric quadrangular pyramid shape.

Each of the plurality of second protruding patterns may have a hemispherical shape.

In the first mode, all the plurality of first light sources and the plurality of second light sources may emit light and in the second mode, the plurality of first light sources may emit light, but the plurality of second light sources may not emit light.

According to embodiments of the present disclosure, some of a plurality of light source units disposed below a display panel may be controlled to emit light according to a driving mode to control both a first area and a second area as a wide field-of-view mode in a first mode and control a first area as a wide field-of-view mode and a second area as a narrow field-of-view mode in a second mode.

According to embodiments of the present disclosure, a first protruding pattern which is disposed on a lower surface of a light guide plate and has a different density in each area is included to improve a viewing angle required for a second area in which a content is displayed at a wide viewing angle or a narrow viewing angle based on the driving mode, according to each mode.

According to embodiments of the present disclosure, a second protruding pattern which is different from the first protruding pattern is disposed in the first area on a lower surface of the light guide plate to improve a viewing angle required for the first area in which a content is displayed at a wide viewing angle regardless of a driving mode.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

1. A display device comprising:
a first light source unit including a plurality of first light sources;
a light controller which is disposed on the first light source unit and includes a plurality of partitions overlapping at least a partial area of an active area;
a second light source unit which is disposed on the light controller and includes a plurality of second light sources;
a light guide plate disposed to be parallel to the second light source unit and configured to guide light provided from the second light source unit; and
a display panel disposed on the light guide plate and configured to display an image using light provided from the first light source unit or the second light source unit,
wherein the light guide plate includes a plurality of first protruding patterns which protrudes from a lower bottom surface and is disposed with a different density in each area.

2. The display device of claim 1,
wherein the active area includes:
a first area in which an image is displayed at a first viewing angle in a first mode and a second mode; and
a second area which is adjacent to the first area in a first direction, and in the second area, an image is displayed at the first viewing angle in the first mode and an image is displayed at a second viewing angle which is smaller than the first viewing angle in the second mode.

3. The display device of claim 2,
wherein the plurality of first protruding patterns is disposed with a first density in the first area and is disposed with a second density which is higher than the first density in the second area.

4. The display device of claim 2,
wherein a placement density of the plurality of first protruding patterns is reduced as being farther from a boundary between the first area and the second area.

5. The display device of claim 4,
wherein the placement density of the plurality of first protruding patterns is reduced in a third area of the first area which is adjacent to the second area as being farther from the boundary between the first area and the second area, and
the plurality of first protruding patterns is disposed with a constant density in a fourth area of the first area which is adjacent to the third area in an opposite direction of the first direction.

6. The display device of claim 4,
wherein a placement density of a first protruding pattern disposed on the second area, among the plurality of first protruding patterns, is reduced toward the first direction, and
the second light source unit is disposed in a side of the light guide plate in the first direction.

7. The display device of claim 2,
wherein the light guide plate further includes a plurality of second protruding patterns which protrudes from a bottom surface and has a shape different from the plurality of first protruding patterns.

8. The display device of claim 7,
wherein the plurality of second protruding patterns is disposed in the first area, but is not disposed in the second area.

9. The display device of claim 8,
wherein in the first area, the plurality of second protruding patterns is disposed with a constant density.

10. The display device of claim 9,
wherein a placement density of the plurality of second protruding patterns disposed in the first area is smaller to a minimum value of a placement density of the plurality of first protruding patterns disposed in the first area.

11. The display device of claim 8,
wherein the plurality of second protruding patterns,
is disposed with a third density in a third area of the first area which is adjacent to the second area, and
is disposed with a fourth density which is higher than the third density in a fourth area of the first area which is adjacent to the third area in an opposite direction of the first direction.

12. The display device of claim 11,
wherein the plurality of second protruding patterns is disposed with a constant density in each of the third area and the fourth area.

13. The display device of claim 11,
wherein in the third area, a placement density of the plurality of second protruding patterns is increased as being farther from a boundary between the first area and the second area, and
in the fourth area, the plurality of second protruding patterns is disposed with a constant density.

14. The display device of claim 1,
wherein each of the plurality of first protruding patterns has an asymmetric quadrangular pyramid shape.

15. The display device of claim 7,
wherein each of the plurality of second protruding patterns has a hemispherical shape.

16. The display device of claim 2,
wherein in the first mode, the plurality of first light sources and the plurality of second light sources emit light, and
in the second mode, the plurality of first light sources emits light, but the plurality of second light sources does not emit light.

17. The display device of claim 1, wherein each of the plurality of partitions has a rectangular shape on a side surface.

18. The display device of claim 1, wherein each of the plurality of partitions has a trapezoidal shape on a side surface.

19. A display device comprising:
a first light source unit including a plurality of first light sources;
a light controller which is disposed on the first light source unit and includes a plurality of partitions overlapping at least a partial area of an active area;
a second light source unit which is disposed on the light controller and includes a plurality of second light sources;
a light guide plate disposed to be parallel to the second light source unit and configured to guide light provided from the second light source unit; and
a display panel disposed on the light guide plate and configured to display an image using light provided from the first light source unit or the second light source unit,
wherein the light guide plate includes a plurality of first protruding patterns and a plurality of second protruding patterns which protrude from a bottom surface.

20. The display device of claim 19,
wherein the active area includes:
a first area in which an image is displayed at a first viewing angle in a first mode and a second mode; and
a second area which is adjacent to the first area in a first direction, and in the second area, an image is displayed at the first viewing angle in the first mode and an image is displayed at a second viewing angle which is smaller than the first viewing angle in the second mode,
wherein the plurality of first protruding patterns is disposed in the first area and the second area, and the plurality of second protruding patterns is disposed in the first area, and
wherein the plurality of first protruding patterns and the plurality of second protruding patterns have different shapes.
